(19) United States
(12) Patent Application Publication
(10) Pub. No.: US 2025/0040274 A1
(43) Pub. Date: Jan. 30, 2025

(54) THIN-FILM TRANSISTOR AND X-RAY SENSOR

(71) Applicant: TIANMA JAPAN, LTD., Kawasaki (JP)

(72) Inventors: Jun TANAKA, Kawasaki (JP); Kazushige TAKECHI, Kawasaki (JP); Hiroyuki SEKINE, Kawasaki (JP); Takayuki ISHINO, Kawasaki (JP); Koichi IWASA, Kawasaki (JP)

(21) Appl. No.: 18/781,161

(22) Filed: Jul. 23, 2024

(30) Foreign Application Priority Data
Jul. 28, 2023 (JP) 2023-123799
Mar. 28, 2024 (JP) 2024-053437

(51) Int. Cl. H01L 27/146; G01T 1/24

(52) U.S. Cl. CPC H01L 27/14614; G01T 1/243; H01L 27/14663

(57) ABSTRACT

A thin-film transistor to be used in an X-ray sensor includes a gate electrode, a semiconductor layer, and a gate insulating layer located between the semiconductor layer and the gate electrode. The gate insulating layer includes a first region having an interface with the gate electrode, a second region having an interface with the semiconductor layer, and a third region located between the first region and the second region. Each of the first region and the second region has a density of electron trap states and a density of hole trap states that are higher than whichever of a density of electron trap states and a density of hole trap states of the third region that is lower.

### CROSS-REFERENCE TO RELATED APPLICATIONS

This non-provisional application claims priority under 35 U.S.C. § 119(a) on Patent Application No. 2023-123799 filed in Japan on Jul. 28, 2023 and Patent Application No. 2024-53437 filed in Japan on Mar. 28, 2024, the entire contents of which are hereby incorporated by reference.

### BACKGROUND

This disclosure relates to the structure of a thin-film transistor to be used in an X-ray sensor.

The technology for non-destructively inspecting the inside of a specimen with an image of X-rays transmitted through the specimen is crucial for the fields of medical and industrial non-destructive testing. Especially, digital radiography (DR) that directly captures an image of transmitted X-rays as electronic data has become widely employed because of availability of quick image reading and image interpretation assistance through image processing. The DR uses a device called flat panel detector (FPD).

The FPDs used for X-ray sensors are generally categorized as a direct conversion type and an indirect conversion type. The direct conversion type of FPDs directly convert X-rays into an electric signal. The indirect conversion type of FPDs include a luminescent material (scintillator) that converts X-rays into light (such as visible light or ultraviolet light) and a photoelectric conversion element array that converts the light into an electric signal in their X-ray detection panels. An FPD includes arrayed pixels each including a conversion element that convers X-rays or light into an electric signal and a switching thin-film transistor for taking out the electric signal.

### SUMMARY

An aspect of this disclosure is a thin-film transistor to be used in an X-ray sensor. The thin-film transistor includes a gate electrode, a semiconductor layer; and a gate insulating layer located between the semiconductor layer and the gate electrode. The gate insulating layer includes a first region having an interface with the gate electrode, a second region having an interface with the semiconductor layer, and a third region located between the first region and the second region, and wherein each of the first region and the second region has a density of electron trap states and a density of hole trap states that are higher than whichever of a density of electron trap states and a density of hole trap states of the third region that is lower.

An aspect of this disclosure is a thin-film transistor to be used in an X-ray sensor. The thin-film transistor includes a gate electrode, a semiconductor layer, and a gate insulating layer located between the semiconductor layer and the gate electrode. The gate insulating layer includes a first region having an interface with the gate electrode and a second region having an interface with the semiconductor layer. Each of the first region and the second region has a density of electron trap states substantially equal to a density of hole trap states.

An aspect of this disclosure is a thin-film transistor to be used in an X-ray sensor. The thin-film transistor includes a gate electrode, a semiconductor layer, and a gate insulating layer located between the semiconductor layer and the gate electrode. The gate insulating layer includes a first region having an interface with the gate electrode, a second region having an interface with the semiconductor layer, and a third region made of a material different from materials of the first region and the second region and located between the first region and the second region. Each of the first region and the second region is made of a nitride.

It is to be understood that both the foregoing general description and the following detailed description are exemplary and explanatory and are not restrictive of this disclosure.

### BRIEF DESCRIPTION OF THE DRAWINGS

FIG. 1 is a block diagram illustrating a configuration example of an X-ray sensor.

FIG. 2 is a circuit diagram illustrating a configuration example of an equivalent circuit of a pixel.

FIG. 3 illustrates a cross-sectional structure of a pixel.

FIG. 4 is a plan diagram of a pixel.

FIG. 5 is a cross-sectional diagram schematically illustrating the structure of a thin-film transistor in a related art.

FIG. 6A illustrates the difference in Vg-Id characteristic of a thin-film transistor having the structure of FIG. 5 between before and after application of a gate voltage of +16 V under 660 Gy of X-rays.

FIG. 6B illustrates the difference in Vg-Id characteristic of a thin-film transistor having the structure of FIG. 5 between before and after application of a gate voltage of −8 V under 660 Gy of X-rays.

FIG. 7 is a cross-sectional diagram schematically illustrating the structure of a thin-film transistor in another related art.

FIG. 8A illustrates the difference in Vg-Id characteristic of a thin-film transistor having the structure of FIG. 7 between before and after application of a gate voltage of +16 V under 660 Gy of X-rays.

FIG. 8B illustrates the difference in Vg-Id characteristic of a thin-film transistor having the structure of FIG. 7 between before and after application of a gate voltage of −8 V under 660 Gy of X-rays.

FIG. 9 provides band diagrams for illustrating the change in the characteristic described with reference to FIGS. 5 to 6B.

FIG. 10 provides band diagrams for illustrating the change in the characteristic described with reference to FIGS. 7 to 8B.

FIG. 11 is a cross-sectional diagram illustrating an example of the structure of a switching thin-film transistor in an embodiment of this specification.

FIG. 12 provides band diagrams of the gate electrode, the gate insulating layer, and the semiconductor layer in a thin-film transistor having the structure described with reference to FIG. 11.

FIG. 13 is a cross-sectional diagram schematically illustrating an example of the structure of a switching thin-film transistor for an X-ray sensor in an embodiment of this specification.

FIG. 14 provides band diagrams for illustrating the movement of carriers when the thin-film transistor in FIG. 13 is being irradiated with X-rays.

FIG. 15 is a cross-sectional diagram illustrating a structural example of a switching thin-film transistor having a top-gate structure.

FIG. 16 is a cross-sectional diagram illustrating a structural example of a switching thin-film transistor having a dual-gate structure.

FIG. 17 is a cross-sectional diagram illustrating a structural example of a switching thin-film transistor having a bottom-gate/bottom contact structure.

FIG. 18 is a cross-sectional diagram illustrating a structural example of a switching thin-film transistor having a dual-gate structure.

FIG. 19 is a cross-sectional diagram illustrating a structural example of a switching thin-film transistor having a dual-gate structure.

FIG. 20 is a cross-sectional diagram illustrating a structural example of a switching thin-film transistor having a dual-gate structure.

FIG. 21 is a cross-sectional diagram illustrating a structural example of a switching thin-film transistor having a dual-gate structure.

FIG. 22A is a cross-sectional diagram schematically illustrating the structure of a thin-film transistor used in an experiment.

FIG. 22B is a cross-sectional diagram schematically illustrating the structure of another thin-film transistor used in the experiment.

FIG. 22C provides X-ray radiation conditions in the X-ray irradiation experiment conducted on the switching thin-film transistors.

FIG. 23A illustrates the difference in Vg-Id characteristic of a thin-film transistor having the structure of FIG. 22A between before and after application of a gate voltage of +15 V under 1000 Gy of X-rays.

FIG. 23B illustrates the difference in Vg-Id characteristic of the thin-film transistor having the structure of FIG. 22A between before and after application of a gate voltage of −15 V under 1000 Gy of X-rays.

FIG. 23C illustrates the difference in Vg-Id characteristic of a thin-film transistor having the structure of FIG. 22B between before and after application of a gate voltage of +15 V under 1000 Gy of X-rays.

FIG. 23D illustrates the difference in Vg-Id characteristic of the thin-film transistor having the structure of FIG. 22B between before and after application of a gate voltage of −15 V under 1000 Gy of X-rays.

FIG. 24 provides results of tests in which different positive and negative Vg stresses were applied to thin-film transistors having the structures of FIGS. 22A and 22B and being irradiated with X-rays.

FIG. 25A is a band diagram for illustrating the movement of carriers when a thin-film transistor having the structure of FIG. 22A is being irradiated with X-rays.

FIG. 25B is another band diagram for illustrating the movement of carriers when a thin-film transistor having the structure of FIG. 22A is being irradiated with X-rays.

FIG. 26A is a band diagram for illustrating the movement of carriers when a thin-film transistor having the structure of FIG. 22B is being irradiated with X-rays.

FIG. 26B is another band diagram for illustrating the movement of carriers when a thin-film transistor having the structure of FIG. 22B is being irradiated with X-rays.

### EMBODIMENTS

Hereinafter, embodiments are described with reference to the accompanying drawings. The embodiments are merely examples to implement this disclosure and are not to limit the technical scope of this disclosure. Some elements in the drawings may be exaggerated in size or shape for clear understanding of description.

### First Embodiment

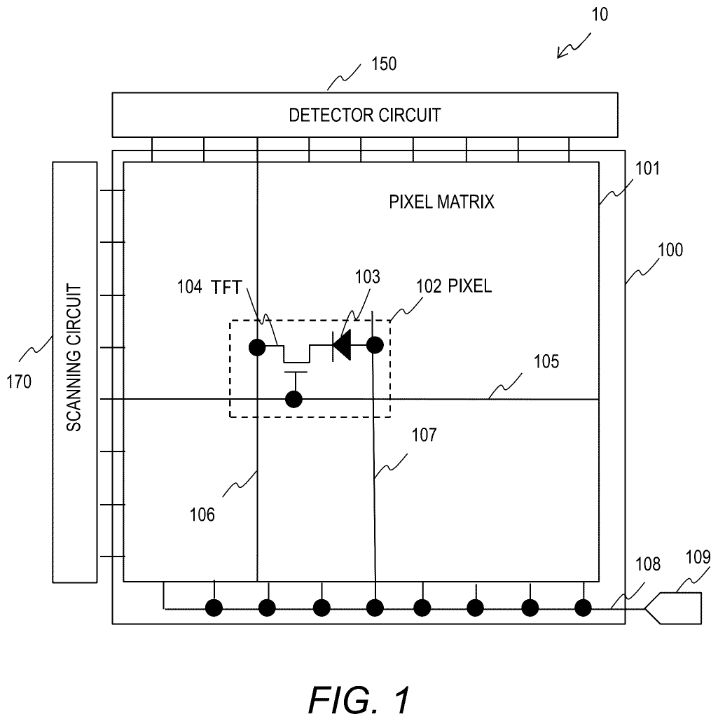

FIG. 1 is a block diagram illustrating a configuration example of an X-ray sensor. The X-ray sensor 10 is an image sensor for imaging X-rays transmitted through an object. The X-ray sensor 10 includes a pixel matrix 101, a scanning circuit 170, and a detector circuit 150. The pixel matrix 101 includes pixels 102 arrayed in a matrix. The pixel matrix 101 is fabricated on a sensor substrate 100. The sensor substrate 100 is an insulating substrate (e.g., a glass substrate).

The pixels 102 are disposed at intersections between a plurality of signal lines 106 and a plurality of gate lines (scanning lines) 105. In FIG. 1, the signal lines 106 are disposed to extend vertically and be horizontally distant from one another and the gate lines 105 are disposed to extend horizontally and be vertically distant from one another. Each pixel 102 is connected to a bias line 107. In FIG. 1, a plurality of bias lines 107 are disposed to extend vertically and be horizontally distant from one another. In FIG. 1, only one of the pixels, one of the signal lines, one of the gate lines, and one of the bias lines are provided with reference signs 102, 106, 105, and 107, respectively. Each signal line 106 is connected to a different pixel column. Each gate line 105 is connected to a different pixel row. The signal line 106 is connected to the detector circuit 150 and the gate line 105 is connected to the scanning circuit 170. Each bias line 107 is connected to a common bias line 108. A bias potential is supplied to a pad 109 of the common bias line 108.

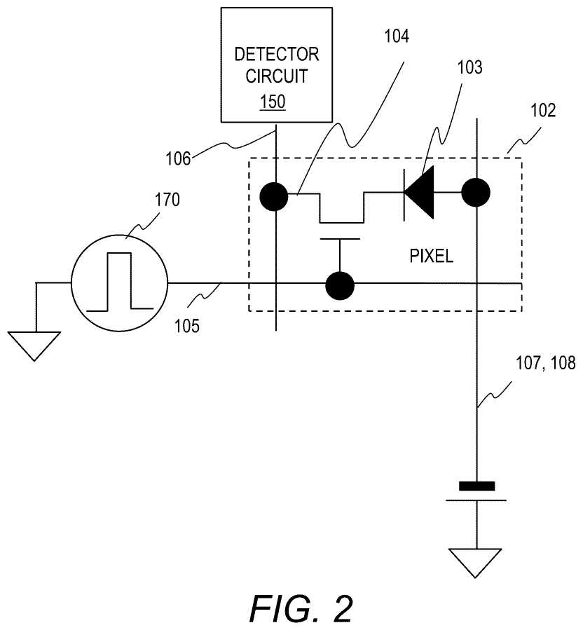

FIG. 2 is a circuit diagram illustrating a configuration example of an equivalent circuit of a pixel 102. The pixel 102 includes a photodiode 103 of a photoelectric conversion element and a thin-film transistor (TFT) 104 of a switching element. In the thin-film transistor 104, the gate is connected to a gate line 105; one source/drain is connected to a signal line 106; and the other source/drain is connected to the cathode of the photodiode 103. In the example of FIG. 2, the anode of the photodiode 103 is connected to a bias line 107.

The thin-film transistor 104 can be an amorphous silicon (a-Si) thin-film transistor, an oxide semiconductor thin-film transistor, or a polysilicon thin-film transistor. The thin-film transistor 104 in the configuration example of FIG. 2 has an n-type of conductivity. The thin-film transistor 104 can have a different conductivity. The following description is provided assuming that the thin-film transistor 104 is an oxide semiconductor thin-film transistor. The oxide semiconductor thin-film transistor exhibits a good switching characteristic.

The X-ray sensor 10 reads a signal of a pixel 102 by taking out signal charge stored in a photodiode 103 in proportion to the amount of X-ray irradiation from the photodiode 103 to the external. The signal charge can be taken out by making the thin-film transistor 104 in the pixel 102 conductive. Specifically, when light enters the photodiode 103, signal charge is generated and stored in the photodiode 103.

The scanning circuit 170 selects gate lines 105 one by one to apply a pulse to make the thin-film transistor 104 conductive. The anode terminal of the photodiode 103 is connected to a bias line 107 and the signal line 106 is supplied with a reference potential by the detector circuit 150. Accordingly, the photodiode 103 is charged with a difference voltage between the bias potential of the bias line 107 and the reference potential. This difference voltage is determined so that the cathode potential is higher than the anode potential to reverse-bias the photodiode 103.

The charge required to recharge the photodiode 103 to the reverse bias voltage depend on the amount of light incident on the photodiode 103. The detector circuit 150 reads the signal charge by integrating the current that flows until the photodiode 103 is recharged to the reverse bias voltage.

The charge stored in the photodiode 103 inevitably decreases because of incident light and dark leakage current that flows even when the photodiode 103 is not irradiated with light. Accordingly, in the thin-film transistor 104 under the operation of signal charge reading, the voltage at the terminal connected to the signal line 106 is equal to or higher than the voltage at the terminal connected to the photodiode 103. That is to say, the terminal connected to the signal line 106 is the drain and the terminal connected to the photodiode 103 is the source in detecting signal charge.

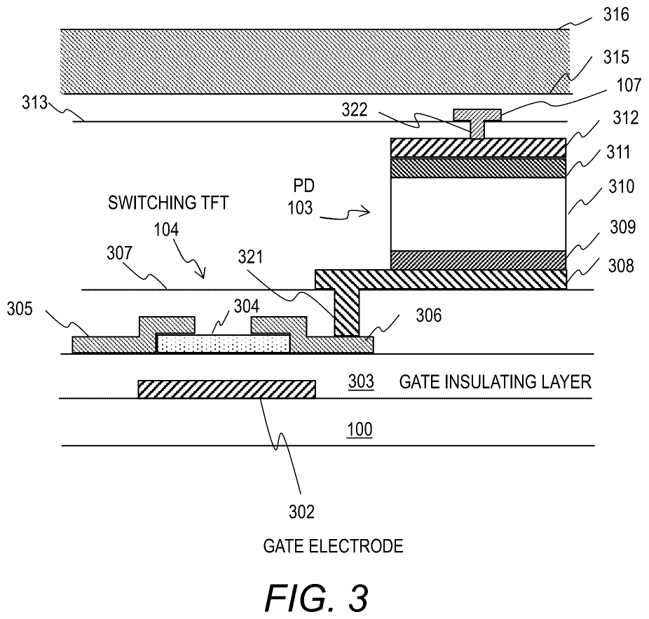

FIG. 3 illustrates a cross-sectional structure of a pixel. In the following description, the side where the test object is to be placed with respect to the X-ray sensor 10 is defined as front. In FIG. 3, the side opposite from the sensor substrate 100 with respect to the photodiode 103 is the front. In the positional relations among the components of a pixel, the side closer to the sensor substrate 100 is referred to as lower side and the opposite side as upper side.

The thin-film transistor 104 and the photodiode 103 included in a pixel each have a layered structure. The thin-film transistor 104 includes a gate electrode 302 provided above an insulating sensor substrate 100, a gate insulating layer 303 above the gate electrode 302, and an oxide semiconductor layer 304 above the gate insulating layer 303.

The thin-film transistor 104 in FIG. 3 has a bottom-gate structure; the gate electrode 302 is located under the oxide semiconductor layer 304. The thin-film transistor 104 further includes a source/drain electrode 305 and another source/drain electrode 306 above the gate insulating layer 303. The source/drain electrodes 305 and 306 are individually connected to the oxide semiconductor layer 304. Each of the source/drain electrodes 305 and 306 is in contact with a side face and a part of the top face of the island-like oxide semiconductor layer 304.

One of the source/drain electrodes 305 and 306 is a source electrode and the other one is a drain electrode depending on the flow of the carriers. In detecting the charge of the photodiode 103, the electrode 305 is a drain electrode and the electrode 306 is a source electrode.

The gate insulating layer 303 is provided to cover the entire gate electrode 302. The gate insulating layer 303 is provided between the gate electrode 302 and the oxide semiconductor layer 304, between the gate electrode 302 and the source/drain electrode 305, and between the gate electrode 302 and the source/drain electrode 306.

A first interlayer insulating layer 307 is provided to cover the entire thin-film transistor 104. Specifically, the first interlayer insulating layer 307 covers the top face of the oxide semiconductor layer 304 and the top faces of the source/drain electrodes 305 and 306.

The sensor substrate 100 can be made of glass or resin. The gate electrode 302 is a conductor and can be made of a metal or impurity-doped silicon. The gate insulating layer 303 can have a single-layer or multilayer structure. Each layer of the gate insulating layer 303 can be made of silicon oxide (SiOx) or silicon nitride (SiNx). The details of the gate insulating layer 303 will be described later.

The oxide semiconductor for the oxide semiconductor layer 304 is an oxide semiconductor including at least one of In, Ga, and Zn, such as amorphous InGaZnO (a-InGaZnO) or microcrystalline InGaZnO. Other oxide semiconductors such as a-InSnZnO and a-InSnZnO can also be employed. The examples described in the following principally employ amorphous or microcrystalline InGaZnO (which can also be expressed as IGZO in the following).

The source/drain electrodes 305 and 306 are conductors and can be made of a metal such as Mo, Ti, Al, or Cr, an alloy thereof, or a laminate of these metals or alloys. The first interlayer insulating layer 307 is an inorganic or organic insulator. Although the thin-film transistor 104 in FIG. 3 has a bottom-gate structure, the thin-film transistor 104 can have a top-gate structure instead.

The photodiode 103 is provided above the first interlayer insulating layer 307. The example of the photodiode 103 in FIG. 3 is a PIN diode. The PIN diode has a thick depletion layer in the film thickness to allow efficient light detection. The photodiode 103 includes layered semiconductors sandwiched between a lower electrode 308 above the first interlayer insulating layer 307 and an upper electrode 312. The lower electrode 308 is connected to the source/drain electrode 306 of the thin-film transistor 104 through the interconnection region in a via hole 321 of the first interlayer insulating layer 307.

The lower electrode 308 is a conductor and can be made of a metal such as Cr, Mo, or Al, an alloy thereof, or a laminate of these metals or alloys. The upper electrode 312 is a transparent electrode that transmits light from a scintillator 316 and can be made of ITO, for example.

The photodiode 103 includes an n-type amorphous silicon layer 309 above the lower electrode 308, an intrinsic amorphous silicon layer 310 above the n-type amorphous silicon layer 309, and a p-type amorphous silicon layer 311 above the intrinsic amorphous silicon layer 310. The upper electrode 312 is provided above the p-type amorphous silicon layer 311. The light to be detected enters the photodiode 103 from above the upper electrode 312 (the p-type amorphous silicon layer 311).

A second interlayer insulating layer 313 is provided to cover the photodiode 103. Specifically, the second interlayer insulating layer 313 is provided above the first interlayer insulating layer 307, a part of the lower electrode 308, and the upper electrode 312. The second interlayer insulating layer 313 is an inorganic or organic insulator.

A bias line 107 is provided above the second interlayer insulating layer 313. The bias line 107 is connected to the upper electrode 312 through an interconnection region provided in a via hole 322 of the second interlayer insulating layer 313. The bias line 107 is a conductor and can be made of a metal such as Mo, Ti, or Al, an alloy thereof, or a laminate of these metals or alloys.

A passivation layer 315 is provided to cover the bias line 107 and the second interlayer insulating layer 313. The passivation layer 315 covers the entire pixel matrix 101. The passivation layer 315 is an inorganic or organic insulator. A scintillator 316 is provided above the passivation layer 315.

The scintillator 316 covers the entire pixel matrix 101. The scintillator 316 emits light by being excited by radioactive rays. Specifically, the scintillator 316 converts the received X-rays into light having a wavelength detectable for the photodiode 103. The photodiode 103 stores signal charge in the amount depending on the light from the scintillator 316.

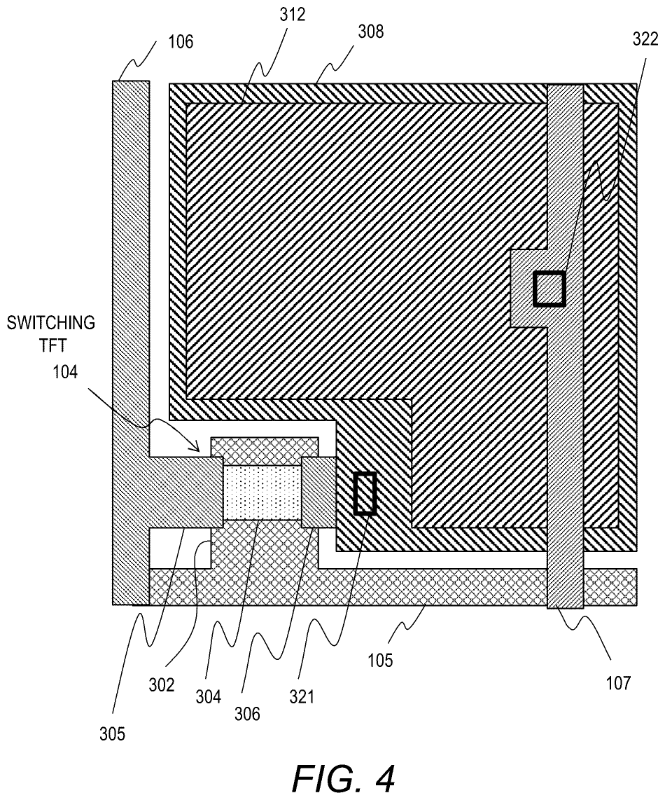

FIG. 4 is a plan diagram of a pixel 102. As illustrated in FIG. 4, a gate line 105 extends from the left to the right of FIG. 4 and a signal line 106 extends from the top to the bottom of FIG. 4. The gate electrode 302 is unseparated from the gate line 105; these are parts of an unseparated metal film. The gate electrode 302 is projecting from the gate line 105 perpendicularly to the direction in which the gate line 105 extends.

The source/drain electrode 305 of the thin-film transistor is unseparated from the signal line 106; these are parts of an unseparated metal film. The source/drain electrode 305 is projecting from the signal line 106 perpendicularly to the direction in which the signal line 106 extends. The source/drain electrode 306 is an island-like electrode and is distant from the source/drain electrode 305.

The oxide semiconductor layer 304 is disposed to overlap the gate electrode 302, when viewed planarly. The source/drain electrode 305 is disposed on one side of the oxide semiconductor layer 304 and the source/drain electrode 306 is disposed on the opposite side. The source/drain electrode 306 is partially covered with the lower electrode 308 of the photodiode 103 and is connected to the lower electrode 308 through a via hole 321.

When the example of FIG. 4 is viewed planarly, the entire upper electrode 312 of the photodiode 103 is within the region of the lower electrode 308. A bias line 107 extends from the bottom to the top of FIG. 4. The bias line 107 overlaps the upper electrode 312 and is connected to the upper electrode 312 through a via hole 322.

Although the configuration example described with reference to FIGS. 1 to 4 includes a photodiode as an element for converting electromagnetic rays to an electric signal, other kinds of elements can be employed. For example, an element that can directly convert X-rays into an electric signal without a scintillator can be employed.

One of the features of an embodiment of this specification is in the structure of a switching thin-film transistor in each pixel of an X-ray sensor. Hereinafter, structures of a thin-film transistor in the embodiments of this specification are described. A switching thin-film transistor to be used in an X-ray sensor is demanded to have some characteristics including high current-driving capability (low delay), low leakage current characteristic (low noise), and high resistance to X-rays (high reliability).

The inventors' research revealed that the structure of the gate insulating layer of a switching thin-film transistor affects the reliability of the thin-film transistor that is being irradiated with X-rays. The switching thin-film transistor exhibits significant variation in its characteristics in response to X-rays. Specifically, the thin-film transistor being irradiated with strong X-rays loses the ON/OFF characteristic when a voltage is applied to the gate electrode. The cause is considered to be the electrons that are generated in the gate insulating film because of irradiation with X-rays and flow into the gate electrode or the semiconductor layer (active layer).

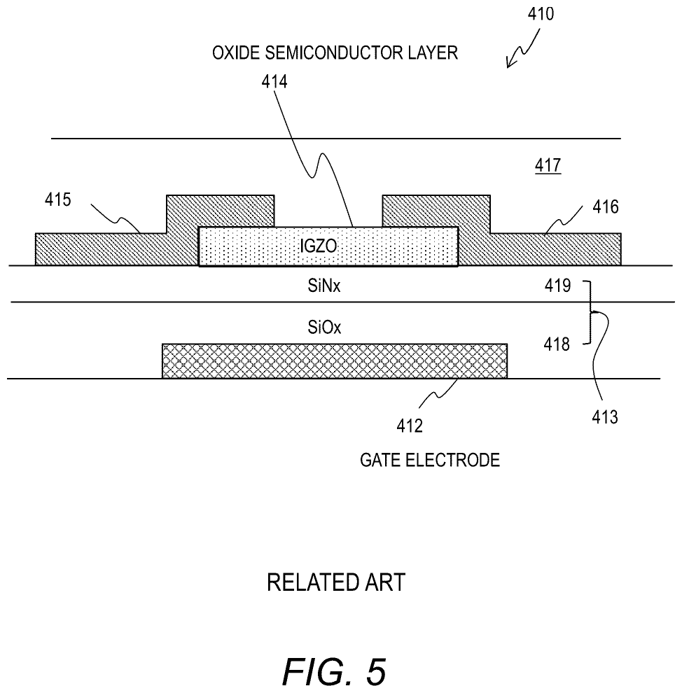

First, structures of a thin-film transistor that can significantly vary in its switching characteristic because of irradiation with X-rays are described. FIG. 5 is a cross-sectional diagram schematically illustrating the structure of a switching thin-film transistor in a related art. The switching thin-film transistor 410 includes a gate electrode 412, a gate insulating layer 413 above the gate electrode 412, and an oxide semiconductor layer 414 above the gate insulating layer 413. The oxide semiconductor layer 414 is made of IGZO. The entire thin-film transistor 410 is covered with an interlayer insulating layer 417.

In the configuration example of FIG. 5, the gate insulating layer 413 has a two-layer structure consisting of a lower insulating layer 418 made of silicon oxide (SiOx) and an upper insulating layer 419 made of silicon nitride (SiNx).

The thin-film transistor 410 has a bottom-gate structure; the gate electrode 412 is located under the oxide semiconductor layer 414. The thin-film transistor 410 further includes a source/drain electrode 415 and another source/drain electrode 416 above the gate insulating layer 413. The source/drain electrodes 415 and 416 are individually connected to the oxide semiconductor layer 414.

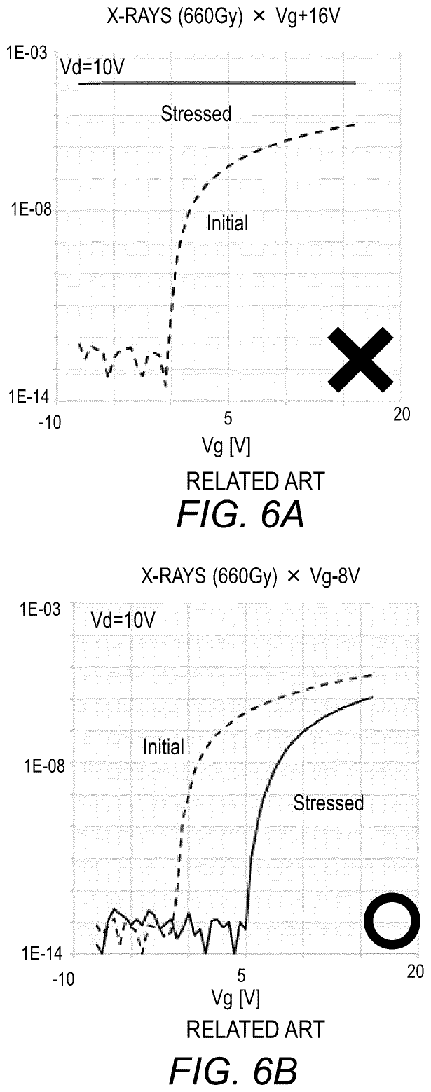

FIG. 6A illustrates the difference in Vg-Id characteristic of a thin-film transistor 410 having the structure of FIG. 5 before and after application of a gate voltage of +16V under X-ray irradiation of 660 Gy. The horizontal axis of the graph represents the gate voltage Vg and the vertical axis represents the drain current Id. The drain voltage Vd was 10 V.

In the graph of FIG. 6A, the broken line represents the Vg-Id characteristic of the thin-film transistor 410 as described above before the positive Vg stress was applied under X ray irradiation. The solid line represents the Vg-Id characteristic of the thin-film transistor 410 as described above after the positive Vg stress was applied under X ray irradiation. As understood from the difference in the characteristic in FIG. 6A, before the positive Vg stress is applied under X ray irradiation, the thin-film transistor 410 properly turns ON/OFF in response to variation in gate voltage. However, after the positive Vg stress is applied under X ray irradiation, the thin-film transistor 410 does not turn OFF within the Vg range of −5 to +15V.

FIG. 6B illustrates the difference in Vg-Id characteristic of a thin-film transistor 410 having the structure of FIG. 5 between before and after application of a gate voltage of −8 V under X-ray irradiation of 660 Gy. The horizontal axis of the graph represents the gate voltage Vg and the vertical axis represents the drain current Id. The drain voltage Vd was 10 V.

In the graph of FIG. 6B, the broken line represents the Vg-Id characteristic of the thin-film transistor 410 as described above before the negative Vg stress was applied under X ray irradiation. The solid line represents the Vg-Id characteristic of the thin-film transistor 410 as described above after the negative Vg stress was applied under X ray irradiation. As understood from the difference in the characteristic in FIG. 6B, the thin-film transistor 410 properly turns ON/OFF in response to variation in gate voltage, although the threshold voltage slightly shifts, after the negative Vg stress is applied under X ray irradiation.

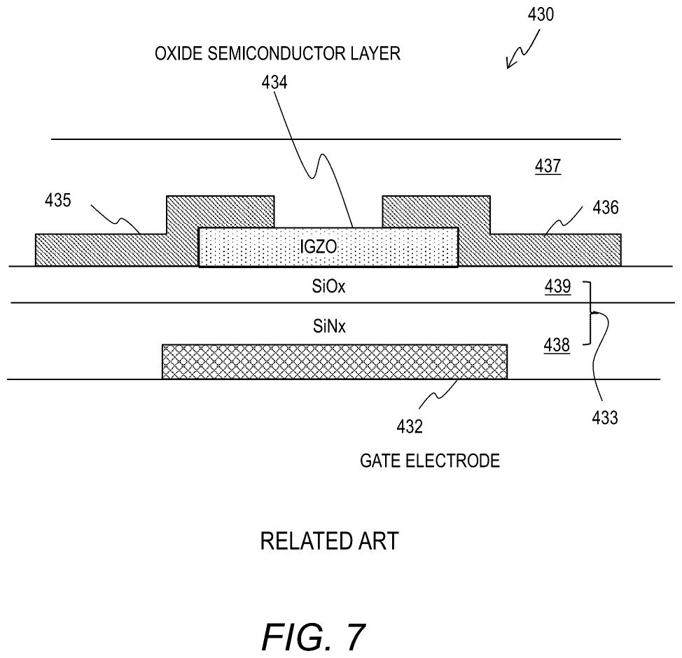

Another example of the structure of a thin-film transistor that can significantly vary in switching characteristic because of irradiation with X-rays is described. FIG. 7 is a cross-sectional diagram schematically illustrating the structure of a switching thin-film transistor in another related art. The switching thin-film transistor 430 includes a gate electrode 432, a gate insulating layer 433 above the gate electrode 432, and an oxide semiconductor layer 434 above the gate insulating layer 433. The oxide semiconductor layer 434 is made of IGZO. The entire thin-film transistor 430 is covered with an interlayer insulating layer 437.

In the configuration example of FIG. 7, the gate insulating layer 433 has a two-layer structure consisting of a lower insulating layer 438 made of silicon nitride (SiNx) and an upper insulating layer 439 made of silicon oxide (SiOx).

The thin-film transistor 430 has a bottom-gate structure; the gate electrode 432 is located under the oxide semiconductor layer 434. The thin-film transistor 430 further includes a source/drain electrode 435 and another source/drain electrode 436 above the gate insulating layer 433. The source/drain electrodes 435 and 436 are individually connected to the oxide semiconductor layer 434.

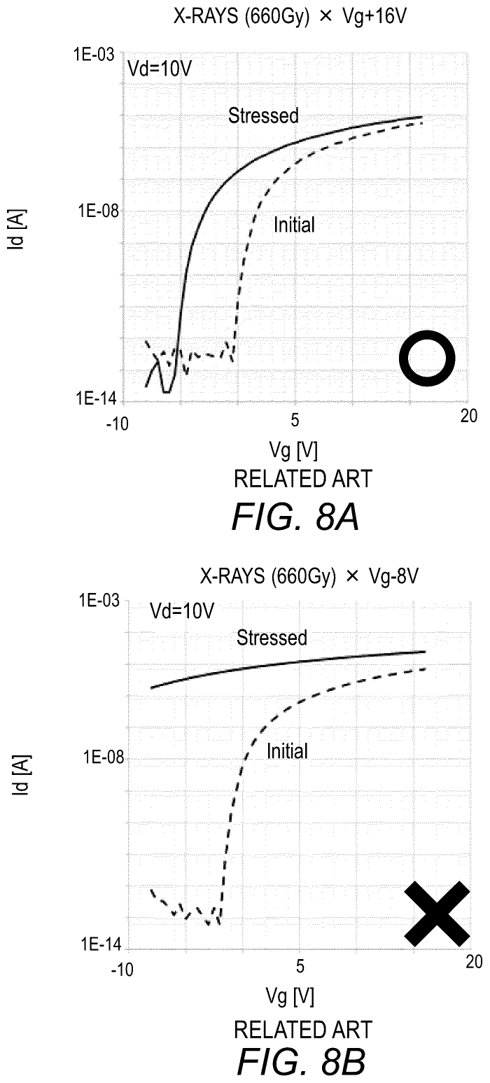

FIG. 8A illustrates the difference in Vg-Id characteristic of a thin-film transistor 430 having the structure of FIG. 7 and between before and after application of a gate voltage of +16 V under 660 Gy of X-rays. The horizontal axis of the graph represents the gate voltage Vg and the vertical axis represents the drain current Id. The drain voltage Vd was 10 V.

In the graph of FIG. 8A, the broken line represents the Vg-Id characteristic of the thin-film transistor 430 as described above before the positive Vg stress was applied under X ray irradiation. The solid line represents the Vg-Id characteristic of the thin-film transistor 430 as described above after the positive Vg stress was applied under X ray irradiation. As understood from the difference in the characteristic in FIG. 8A, the thin-film transistor 430 properly turns ON/OFF in response to variation in gate voltage, although the threshold voltage slightly shifts, after the positive Vg stress is applied under X ray irradiation.

FIG. 8B illustrates the difference in Vg-Id characteristic of a thin-film transistor 430 having the structure of FIG. 7 between before and after application of a gate voltage of −8 V under 660 Gy of X-rays. The horizontal axis of the graph represents the gate voltage Vg and the vertical axis represents the drain current Id. The drain voltage Vd was 10 V.

In the graph of FIG. 8B, the broken line represents the Vg-Id characteristic of the thin-film transistor 430 as described above before the negative Vg stress was applied under X ray irradiation. The solid line represents the Vg-Id characteristic of the thin-film transistor 430 as described above after the negative Vg stress was applied under X ray irradiation. As understood from the difference in the characteristic in FIG. 8B, before the negative Vg stress is applied under X ray irradiation, the thin-film transistor 430 properly turns ON/OFF in response to variation in gate voltage. However, after the negative Vg stress is applied under X ray irradiation, the thin-film transistor 430 does not turn OFF within the Vg range of −5 to +15V.

The study of the foregoing two examples revealed that the density of trap states for electrons (e) and holes (h) (these can be collectively called carriers) of the gate insulating layer are major causes of the change in switching characteristic of a thin-film transistor. Specifically, silicon oxide and silicon nitride have many hole trap states (a high density of hole trap states). Silicon nitride has many electron trap states (a high density of electron trap states). However, silicon oxide has much fewer electron trap states than hole trap states or the electron trap states of silicon nitride. Accordingly, it is inferred that electrons excited in silicon oxide (SiOx) flow into the gate electrode and/or the semiconductor active layer to break the balance of the charge in the gate insulating layer, causing the above-described problem.

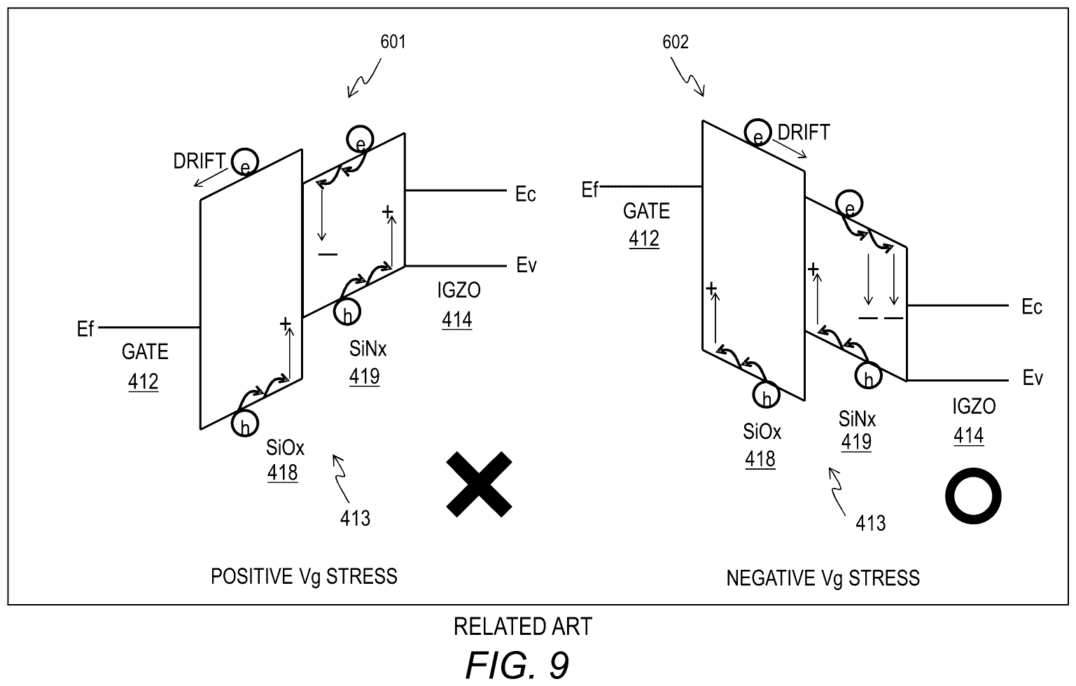

FIG. 9 provides band diagrams for illustrating the change in the characteristic described with reference to FIGS. 5 to 6B. The band diagram 601 illustrates electron energy levels in the gate electrode 412, the gate insulating layer 413, and the oxide semiconductor layer 414 when a positive gate voltage (positive Vg stress) is applied to the thin-film transistor 410 under X ray irradiation as described with reference to FIG. 6A. In the diagram 601, Ec represents the lower edge of the conduction band of the semiconductor layer or the insulating films; Ev represents the upper edge of the valence band of the semiconductor layer or the insulating films; and Ef represents the fermi level of the metal layer. The diagram 601 is configured so that the band gaps of silicon oxide, silicon nitride, and oxide semiconductor are approximately 8.8 eV, 5.1 eV, and 3.1 eV, respectively.

The electrons (e) generated in the lower silicon oxide layer 418 exit to the gate electrode 412 having lower energy levels. The holes (h) generated in the silicon oxide layer 418 are trapped in the hole trap states in the silicon oxide layer 418.

The electrons (e) generated in the upper silicon nitride layer 419 are trapped in the electron trap states in the silicon nitride layer 419. The holes (h) generated in the silicon nitride layer 419 are trapped in the hole trap states in the silicon nitride layer 419.

Since only electrons exit to the gate electrode 412 as described above, the number of positive ions in the gate insulating layer 413 becomes larger than the number of negative ions therein. Accordingly, the threshold voltage Vth of the thin-film transistor 410 significantly shifts toward the negative side. As a result, the thin-film transistor 410 loses its switching characteristic.

The band diagram 602 illustrates electron energy levels in the gate electrode 412, the gate insulating layer 413, and the oxide semiconductor layer 414 when a negative gate voltage (negative Vg stress) is applied to the thin-film transistor 410 under X ray irradiation as described with reference to FIG. 6B. The reference signs Ec, Ev, and Ef in the diagram 602 are the same as those in the diagram 601. The diagram 602 is configured so that the band gaps of silicon oxide, silicon nitride, and oxide semiconductor are approximately 8.8 eV, 5.1 eV, and 3.1 eV, respectively.

The electrons (e) generated in the lower silicon oxide layer 418 drift to the upper silicon nitride layer 419 having lower energy levels and are trapped in the electron trap states in the silicon nitride layer 419. The holes (h) generated in the silicon oxide layer 418 are trapped in the hole trap states in the silicon oxide layer 418.

The electrons (e) generated in the upper silicon nitride layer 419 are trapped in the electron trap states in the silicon nitride layer 419. The holes (h) generated in the silicon nitride layer 419 are trapped in the hole trap states in the silicon nitride layer 419.

Since the electrons and holes are trapped in the trap states in the gate insulating layer 413 as described above, the number of positive ions in the gate insulating layer 413 is balanced with the number of negative ions therein. Accordingly, the threshold voltage Vth of the thin-film transistor 410 substantially does not shift. Although a small shift of the threshold voltage Vth may occur in an actual situation, the thin-film transistor 410 can keep its proper switching characteristic.

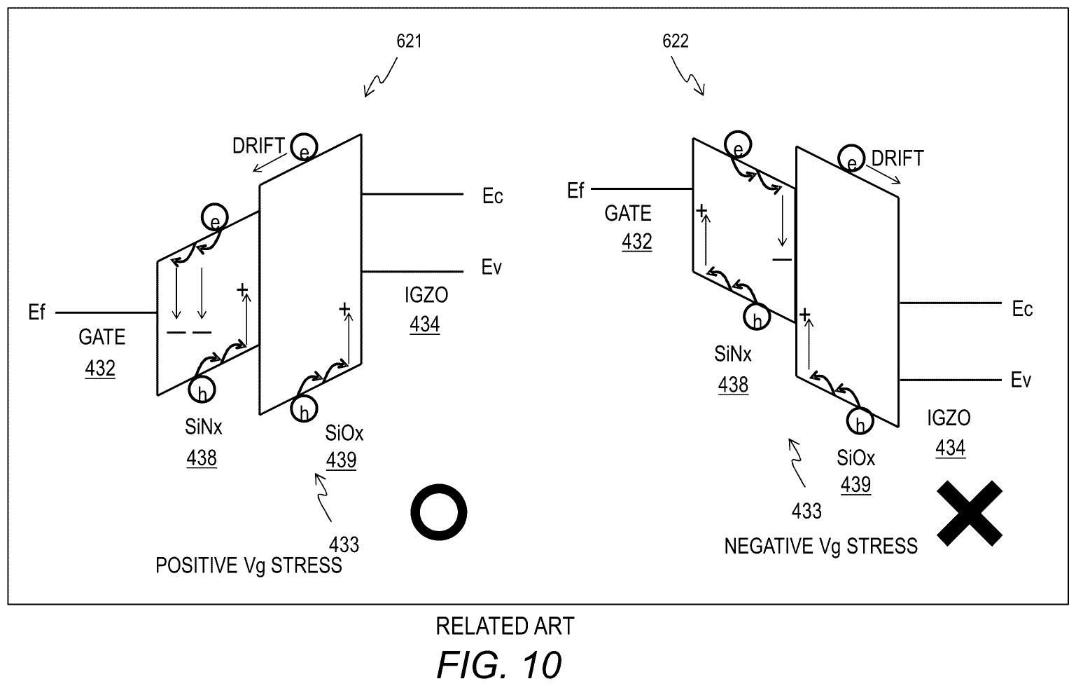

Next, the change in the characteristic described with reference to FIGS. 7 to 8B is described. FIG. 10 provides band diagrams for illustrating the change in the characteristic described with reference to FIGS. 7 to 8B. The band diagram 621 illustrates electron energy levels in the gate electrode 432, the gate insulating layer 433, and the oxide semiconductor layer 434 when a positive gate voltage (positive Vg stress) is applied to the thin-film transistor 430 under X ray irradiation as described with reference to FIG. 8A. In the band diagram 621, the reference signs Ec, Ev, and Ef are the same as those in the diagrams 601 and 602 in FIG. 9. The diagram 621 is configured so that the band gaps of silicon oxide, silicon nitride, and oxide semiconductor are approximately 8.8 eV, 5.1 eV, and 3.1 eV, respectively.

The electrons (e) generated in the upper silicon oxide layer 439 drift to the lower silicon nitride layer 438 having lower energy levels and are trapped in the electron trap states in the silicon nitride layer 438. The holes (h) generated in the silicon oxide layer 439 are trapped in the hole trap states in the silicon oxide layer 439.

The electrons (e) generated in the lower silicon nitride layer 438 are trapped in the electron trap states in the silicon nitride layer 438. The holes (h) generated in the silicon nitride layer 438 are trapped in the hole trap states in the silicon nitride layer 438.

Since the electrons and holes are trapped in the trap states in the gate insulating layer 433 as described above, the number of positive ions in the gate insulating layer 433 is balanced with the number of negative ions therein. Accordingly, the threshold voltage Vth of the thin-film transistor 430 substantially does not shift. Although a small shift of the threshold voltage Vth may occur in an actual situation, the thin-film transistor 430 can keep its proper switching characteristic.

The band diagram 622 illustrates electron energy levels in the gate electrode 432, the gate insulating layer 433, and the oxide semiconductor layer 434 when a negative gate voltage (negative Vg stress) is applied to the thin-film transistor 430 under X ray irradiation as described with reference to FIG. 8B. In the band diagram 622, the reference signs Ec, Ev, and Ef are the same as those in the diagrams 601 and 602 in FIG. 9 and the diagram 621 in FIG. 10. The diagram 622 is configured so that the band gaps of silicon oxide, silicon nitride, and oxide semiconductor are approximately 8.8 eV, 5.1 eV, and 3.1 eV, respectively.

The electrons (e) generated in the upper silicon oxide layer 439 exit to the oxide semiconductor layer (active layer) 434 having lower energy levels. The holes (h) generated in the silicon oxide layer 439 are trapped in the hole trap states in the silicon oxide layer 439.

The electrons (e) generated in the lower silicon nitride layer 438 are trapped in the electron trap states in the silicon nitride layer 438. The holes (h) generated in the silicon nitride layer 438 are trapped in the hole trap states in the silicon nitride layer 438.

Since only electrons exit to the oxide semiconductor layer 434 as described above, the number of positive ions in the gate insulating layer 433 becomes larger than the number of negative ions therein. Accordingly, the threshold voltage Vth of the thin-film transistor 430 significantly shifts toward the negative side. As a result, the thin-film transistor 430 loses its switching characteristic.

In view of the above, the gate insulating layer of the thin-film transistor in an embodiment of this specification has electron trap states and hole trap states in both of the region having an interface with the gate electrode and the region having an interface with the semiconductor layer (active layer). This configuration prevents carriers (electrons or holes) from exiting from the gate insulating layer to the gate electrode or the semiconductor layer, reducing degradation in switching characteristic of the thin-film transistor.

Each region has a density of electron trap states and a density of hole trap states high enough to trap the electrons and holes generated in the gate insulating layer because of irradiation with X-rays and prevent them from exiting to the gate electrode or the semiconductor layer. Then, the thin-film transistor can reliably prevent its switching characteristic from getting lost. The density of electron trap states and the density of hole trap states can be not less than 7e11 cm⁻² eV⁻¹. The inventors obtained this value through study of silicon nitride (SiNx). The value of the density of the trap states for the region of the gate insulating layer having an interface with the semiconductor layer or the gate electrode can be determined appropriately depending on the design of the thin-film transistor.

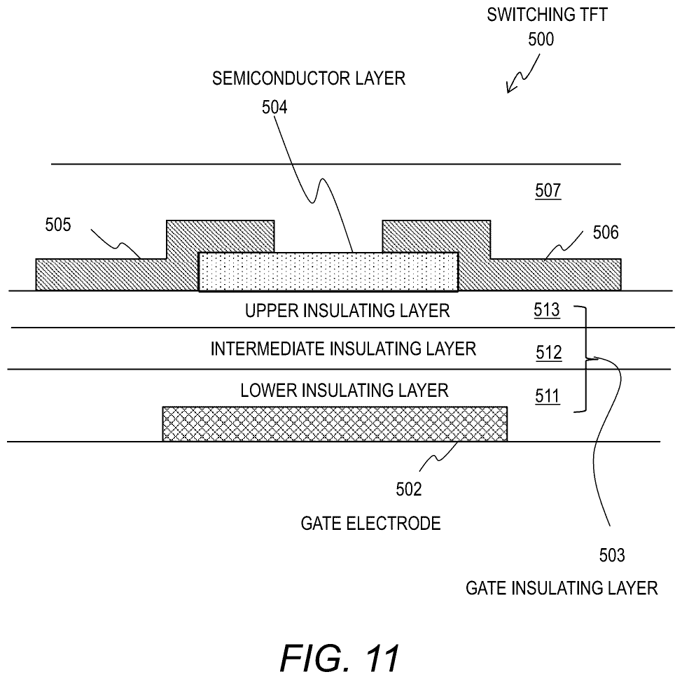

FIG. 11 is a cross-sectional diagram illustrating an example of the structure of a switching thin-film transistor in an embodiment of this specification. The thin-film transistor 500 includes a gate electrode 502, a gate insulating layer 503 above the gate electrode 502, and a semiconductor layer 504 above the gate insulating layer 503. The semiconductor layer 504 can be made of oxide semiconductor, amorphous silicon, or polysilicon. The entire thin-film transistor 500 is covered with an interlayer insulating layer 507.

The gate insulating layer 503 in the configuration example of FIG. 11 has a three-layer structure consisting of a lower insulating layer 511, an intermediate insulating layer 512 above the lower insulating layer 511, and an upper insulating layer 513 above the intermediate insulating layer 512. These are the lower region, the intermediate region, and the upper region of the gate insulating layer 503. The intermediate insulating layer 512 is in contact with the lower insulating layer 511 and the upper insulating layer 513 and has interfaces with them. In the gate insulating layer 503, the lower insulating layer 511 has an interface with the gate electrode 502 and the upper insulating layer 513 has an interface with the semiconductor layer 504.

The thin-film transistor 500 has a bottom-gate structure; the gate electrode 502 is located under the semiconductor layer 504. The thin-film transistor 500 further includes a source/drain electrode 505 and another source/drain electrode 506 above the gate insulating layer 503. The source/drain electrodes 505 and 506 are individually connected to the semiconductor layer 504. For the gate electrode 502, the source/drain electrodes 505 and 506, and the interlayer insulating layer 507, the description about the components having the same names provided with reference to FIG. 3 or 4 is applicable.

Regarding the gate insulating layer 503, both of the density of electron trap states and the density of hole trap states of the lower insulating layer 511 are higher than the density of electron trap states or the density of hole trap states of the intermediate insulating layer 512, whichever is lower. In similar, both of the density of electron trap states and the density of hole trap states of the upper insulating layer 513 are higher than the density of electron trap states or the density of hole trap states of the intermediate insulating layer 512, whichever is lower.

For example, assuming that the intermediate insulating layer 512 has a density of electron trap states lower than the density of hole trap states, the density of the electron trap states and the hole trap states of the lower insulating layer 511 and the upper insulating layer 513 are all higher than the density of electron trap states of the intermediate insulating layer 512.

The lower insulating layer 511 and the upper insulating layer 513 trap not only electrons and holes generated therein because of irradiation with X-rays but also electrons or holes generated in and drifting from the intermediate insulating layer 512. As a result, the thin-film transistor 500 can reduce the shift of the threshold voltage Vth caused by drift of electrons and/or holes from the gate insulating layer 503 to the gate electrode 502 or the semiconductor layer 504 and prevent its switching characteristic from getting lost.

Various materials are known for the gate insulating layer of the switching thin-film transistor in an X-ray sensor. Common gate insulating materials have densities of hole trap states high enough to trap the holes generated in the material because of irradiation with X-rays and prevent their drift to an adjoining layer. However, some of the materials, like silicon oxide (SiOx), have low densities of electron trap states. For this reason, the upper and lower insulating layers can be made of a material having a higher density of electron trap states than that of the intermediate insulating layer.

For example, the lower insulating layer 511 has a thickness of not less than 100 nm and the upper insulating layer 513 has a thickness of not less than 20 nm. In other structures, the insulating layer having an interface with the gate electrode can have a thickness of not less than 100 nm and the insulating layer having an interface with the semiconductor layer can have a thickness of not less than 20 nm.

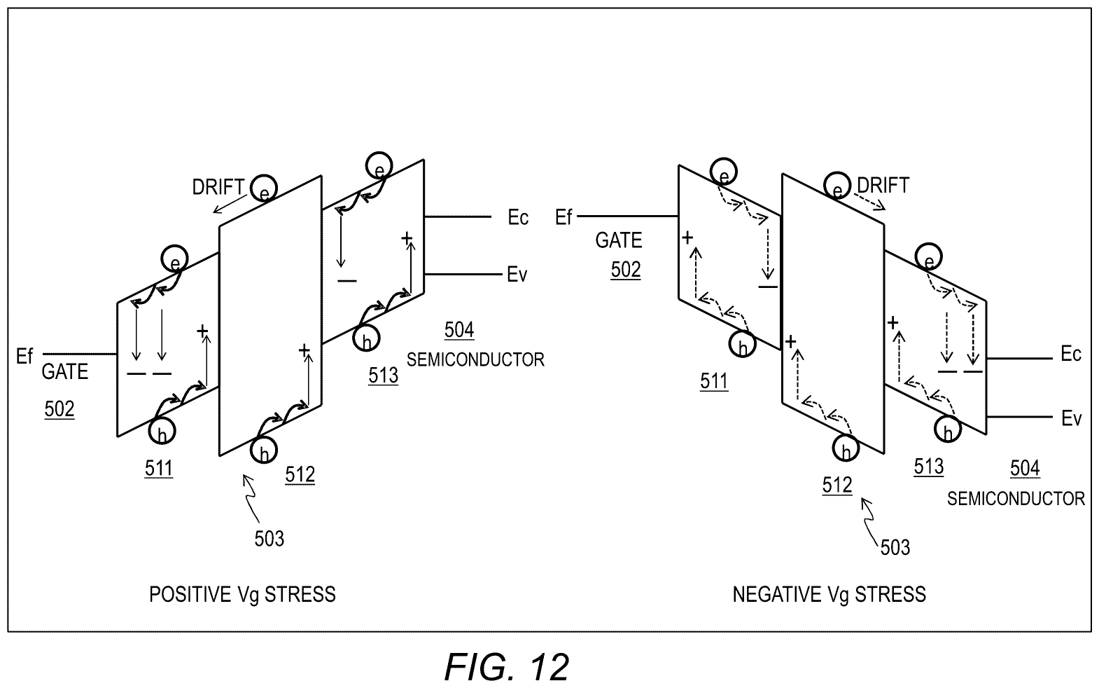

FIG. 12 provides band diagrams of the gate electrode 502, the gate insulating layer 503, and the semiconductor layer 504 in a thin-film transistor having the structure described with reference to FIG. 11. The solid arrow lines represent the direction of travel of carriers when a positive gate voltage is being applied; the broken arrow lines represent the direction of travel of carriers when a negative gate voltage is being applied; Ec represents the lower edges of the conduction bands of the semiconductor layer 504, the upper insulating layer 513, the intermediate insulating layer 512, and the lower insulating layer 511; Ev represents the upper edges of the valence bands of the semiconductor layer 504, the upper insulating layer 513, the intermediate insulating layer 512, and the lower insulating layer 511; and Ef represents the fermi level of the gate electrode 502 (the metal layer). The diagrams are configured so that the band gaps of silicon oxide, silicon nitride, and oxide semiconductor are approximately 8.8 eV, 5.1 eV, and 3.1 eV, respectively.

As described above, the lower insulating layer 511 and the upper insulating layer 513 have densities of electron trap states and densities of hole trap states higher than the lower density of carrier trap states of the intermediate insulating layer 512. Accordingly, the electrons (e) and holes (h) induced by X-rays are trapped before flowing into the gate electrode 502 or the semiconductor layer 504, reducing the threshold voltage shift caused by irradiation with X-rays.

The intermediate insulating layer 512 is made of a material different from the materials of the lower insulating layer 511 and the upper insulating layer 513. The lower insulating layer 511 and the upper insulating layer 513 can be made of the same material or different materials. A plurality of intermediate insulating layers can be provided between the lower insulating layer 511 and the upper insulating layer 513. The above-described relations of the intermediate insulating layer 512 to the lower and upper insulating layers 511 and 513 apply to the relations of at least one or each intermediate insulating layer to the lower and upper insulating layers 511 and 513.

As described with reference to FIGS. 5 to 10, the density of electron trap states of silicon oxide being much lower than its density of hole trap states can cause a large threshold voltage shift to a thin-film transistor. The thin-film transistor for an X-ray sensor in an embodiment of this specification include a gate insulating layer having substantially equal density of electron trap states and density of hole trap states in the regions having interfaces with the semiconductor layer and the gate electrode.

Taking an example of a gate insulating layer having a three-layer structure, the density of electron trap states can be substantially equal to the density of hole trap states in both of the lower insulating layer and the upper insulating layer. Then, electrons and holes induced by X-rays are trapped before flowing into the gate electrode and the semiconductor layer, making the threshold voltage shift caused by X-ray irradiation small.

Gate insulating materials having high hydrogen concentration have high density of electron trap states and density of hole trap states. In the thin-film transistor for an X-ray sensor in an embodiment of this specification, the insulating layer having an interface with the gate electrode has higher hydrogen concentration than the intermediate insulating layer. In similar, the insulating layer having an interface with the semiconductor layer has higher hydrogen concentration than the intermediate insulating layer. For example, the insulating layer having an interface with the gate electrode or the semiconductor layer has a hydrogen concentration not less than 3.4e22 atoms/cc. The intermediate insulating layer has a hydrogen concentration not more than 1.2e21 atoms/cc.

The gate insulating layer satisfies the above-described configurations, specifically the relation of the density of carrier trap states between the intermediate insulating layer and the upper or lower insulating layer, the relation between the density of electron trap states and the density of hole trap states in each of the upper and lower insulating layers, and the relation of the hydrogen concentration, in any one of these, any combination of some of these, or all of these. The same applies to the configurations described in the following.

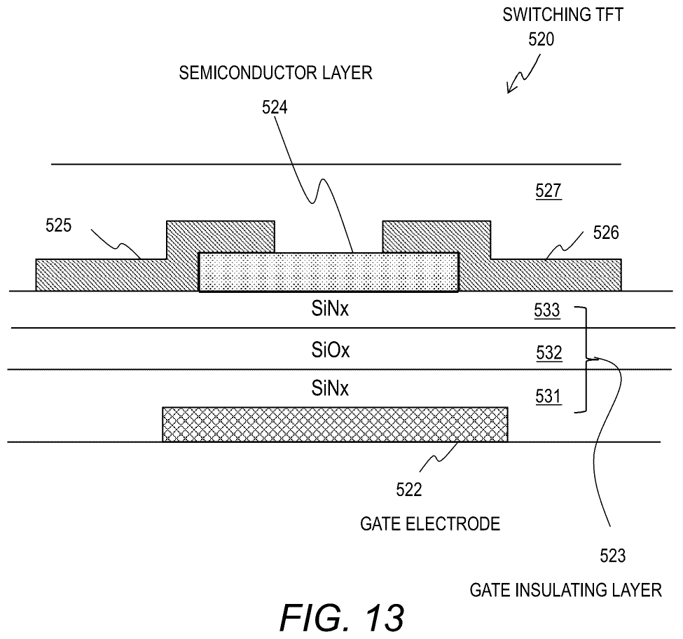

FIG. 13 is a cross-sectional diagram schematically illustrating an example of the structure of a switching thin-film transistor for an X-ray sensor in an embodiment of this specification. The thin-film transistor 520 includes a gate electrode 522, a gate insulating layer 523 above the gate electrode 522, and a semiconductor layer 524 above the gate insulating layer 523. The semiconductor layer 524 can be made of oxide semiconductor, amorphous silicon, or polysilicon. The entire thin-film transistor 520 is covered with an interlayer insulating layer 527.

The gate insulating layer 523 in the configuration example of FIG. 13 has a three-layer structure consisting of a lower silicon nitride (SiNx) layer 531, a silicon oxide (SiOx) layer 532 above the lower silicon nitride layer 531, and an upper silicon nitride layer 533 above the silicon oxide layer 532. These are the lower region, the intermediate region, and the upper region of the gate insulating layer 523.

The silicon oxide layer 532 of an intermediate insulating layer is in contact with the lower silicon nitride layer 531 and the upper silicon nitride layer 533 and has interfaces with them. In the gate insulating layer 523, the lower silicon nitride layer 531 has an interface with the gate electrode 522 and the upper silicon nitride layer 533 has an interface with the semiconductor layer 524.

The thin-film transistor 520 has a bottom-gate structure; the gate electrode 522 is located under the semiconductor layer 524. The thin-film transistor 520 further includes a source/drain electrode 525 and another source/drain electrode 526 above the gate insulating layer 523. The source/drain electrodes 525 and 526 are individually connected to the semiconductor layer 524. For the gate electrode 522, the source/drain electrodes 525 and 526, and the interlayer insulating layer 527, the description on the components having the same names provided with reference to FIG. 3 or 4 is applicable.

As described with reference to FIGS. 5 to 10, a silicon nitride layer has both electron trap states and hole trap states and traps not only electrons and holes generated in the silicon nitride layer but also electrons coming from a silicon oxide layer. The lower silicon nitride layer 531 and the upper silicon nitride layer 533 trap electrons generated in the silicon oxide layer 532 because of irradiation with X-rays and drifting therefrom before reaching the semiconductor layer 524 or the gate electrode 522. As a result, the thin-film transistor 520 can reduce the shift of the threshold voltage Vth and prevent its switching characteristic from getting lost.

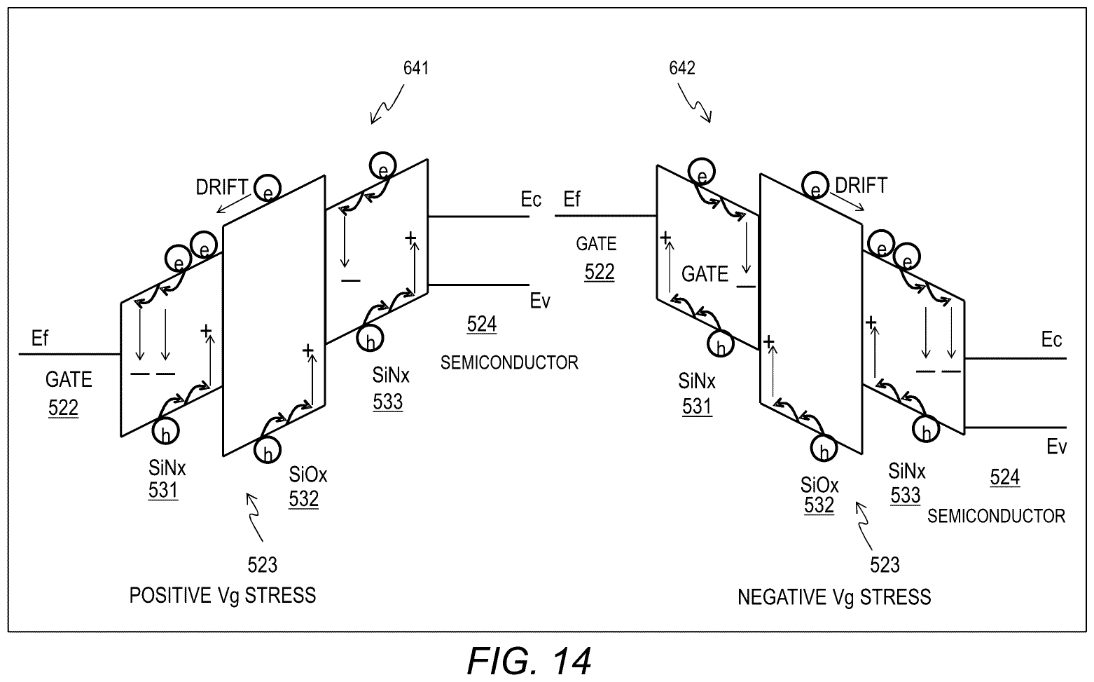

FIG. 14 provides band diagrams for illustrating the movement of carriers when the thin-film transistor 520 in FIG. 13 is being irradiated with X-rays. The band diagram 641 illustrates the electron energy levels of the gate electrode 522, the gate insulating layer 523, and the oxide semiconductor layer 524 when a positive gate voltage is applied to the thin-film transistor 520 under X ray irradiation. In FIG. 14, Ec represents the lower edges of the conduction bands of the semiconductor layer 524, the upper insulating layer 533, the intermediate insulating layer 532, and the lower insulating layer 531; Ev represents the upper edges of the valence bands of the semiconductor layer 524, the upper insulating layer 533, the intermediate insulating layer 532, and the lower insulating layer 531; and Ef represents the fermi level of the gate electrode 522 (the metal layer). The diagram 641 is configured so that the band gaps of silicon oxide, silicon nitride, and oxide semiconductor are approximately 8.8 eV, 5.1 eV, and 3.1 eV, respectively.

The electrons (e) generated in the lower silicon nitride layer 531 because of X-rays are trapped in the electron trap states in the lower silicon nitride layer 531. The holes (h) generated in the lower silicon nitride layer 531 are trapped in the hole trap states in the lower silicon nitride layer 531.

In similar, the electrons (e) generated in the upper silicon nitride layer 533 because of X-rays are trapped in the electron trap states in the upper silicon nitride layer 533. The holes (h) generated in the upper silicon nitride layer 533 are trapped in the hole trap states in the upper silicon nitride layer 533.

The electrons (e) generated in the silicon oxide layer 532 because of X-rays drift to the lower silicon nitride layer 531 having lower energy levels and are trapped in the electron trap states in the lower silicon nitride layer 531. The holes (h) generated in the silicon oxide layer 532 are trapped in the hole trap states in the silicon oxide layer 532.

The band diagram 642 illustrates the electron energy levels of the gate electrode 522, the gate insulating layer 523, and the oxide semiconductor layer 524 when a negative gate voltage is applied to the thin-film transistor 520 under X ray irradiation. The diagram 642 is configured so that the band gaps of silicon oxide, silicon nitride, and oxide semiconductor are approximately 8.8 eV, 5.1 eV, and 3.1 eV, respectively.

The electrons (e) generated in the lower silicon nitride layer 531 because of X-rays are trapped in the electron trap states in the lower silicon nitride layer 531. The holes (h) generated in the lower silicon nitride layer 531 are trapped in the hole trap states in the lower silicon nitride layer 531.

In similar, the electrons (e) generated in the upper silicon nitride layer 533 because of X-rays are trapped in the electron trap states in the upper silicon nitride layer 533. The holes (h) generated in the upper silicon nitride layer 533 are trapped in the hole trap states in the silicon nitride layer 533.

The electrons (e) generated in the silicon oxide layer 532 because of X-rays drift to the upper silicon nitride layer 533 having lower energy levels and are trapped in the electron trap states in the upper silicon nitride layer 533. The holes (h) generated in the silicon oxide layer 532 are trapped in the hole trap states in the silicon oxide layer 532.

Since the electrons and holes are trapped in the trap states in the gate insulating layer 523 as described above, the number of positive ions in the gate insulating layer 523 is balanced with the number of negative ions therein. Accordingly, the threshold voltage Vth of the thin-film transistor 520 substantially does not shift. The thin-film transistor 520 can keep its proper switching characteristic.

Various insulating materials can be employed for the gate insulating layer 523 of the configuration example in FIG. 13. Instead of silicon nitride, an insulating nitride such as aluminum nitride (AlNx), gallium nitride (GaNx), or indium nitride (InNx) can be employed for the upper insulating layer and/or the lower insulating layer. The gate insulating layer can have a single-layer structure. Instead of silicon oxide, an insulating oxide such as silicon oxynitride (SiON) or alumina (AlOx) can be employed for the intermediate insulating layer. For the intermediate insulating layer, any insulating material that is applicable to a switching thin-film transistor for an X-ray sensor can be employed.

Hereinafter, other structural examples of the gate of a switching thin-film transistor are described. The foregoing examples of thin-film transistors have a bottom-gate structure. In other examples, the thin-film transistor can have a top-gate structure or a dual-gate structure having a top gate and a bottom gate. The description about the material and structure of the gate insulating layer and the material of other components of the foregoing thin-film transistors having a bottom-gate structure is applicable to thin-film transistors having other gate structures.

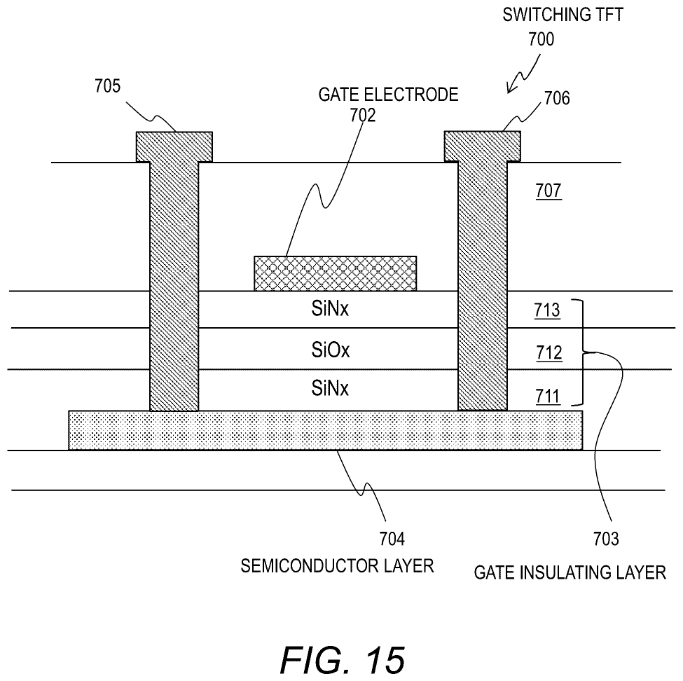

FIG. 15 is a cross-sectional diagram illustrating a structural example of a switching thin-film transistor having a top-gate structure. The thin-film transistor 700 includes a semiconductor layer 704, a gate insulating layer 703 above the semiconductor layer 704, and a gate electrode 702 above the gate insulating layer 703. The semiconductor layer 704 can be made of oxide semiconductor, amorphous silicon, or polysilicon.

The gate insulating layer 703 in the configuration example of FIG. 15 has a three-layer structure consisting of a lower silicon nitride layer 711, a silicon oxide layer 712 above the lower silicon nitride layer 711, and an upper silicon nitride layer 713 above the silicon oxide layer 712.

The silicon oxide layer 712 of an intermediate insulating layer is in contact with the lower silicon nitride layer 711 and the upper silicon nitride layer 713 and has interfaces with them. In the gate insulating layer 703, the lower silicon nitride layer 711 has an interface with the semiconductor layer 704 and the upper silicon nitride layer 713 has an interface with the gate electrode 702.

The thin-film transistor 700 has a top-gate structure; the gate electrode 702 is located above the semiconductor layer 704. The thin-film transistor 700 further includes a source/drain electrode 705 and another source/drain electrode 706. The source/drain electrodes 705 and 706 extend through an interlayer insulating layer 707 and the gate insulating layer 703 to be connected to the semiconductor layer 704. For the gate insulating layer 703, the foregoing description provided with reference to the thin-film transistors having a bottom-gate structure is applicable. For the gate electrode 702, the source/drain electrodes 705 and 706, and the interlayer insulating layer 707, the foregoing description about the components having the same names provided with reference to FIG. 3 or 4 is applicable.

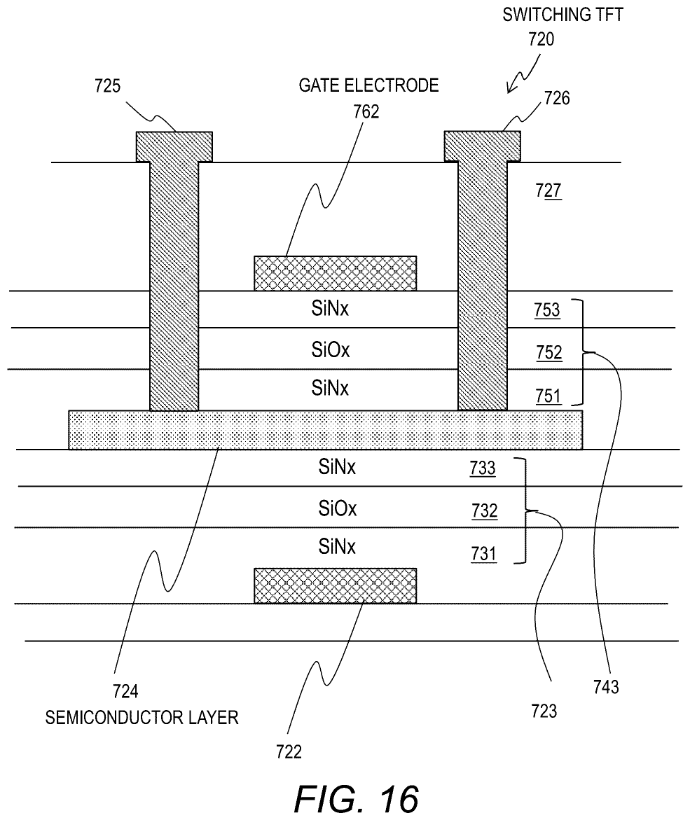

FIG. 16 is a cross-sectional diagram illustrating a structural example of a switching thin-film transistor having a dual-gate structure. The thin-film transistor 720 includes a gate electrode 722, a gate insulating layer 723 above the gate electrode 722, and a semiconductor layer 724 above the gate insulating layer 723. The semiconductor layer 724 can be made of oxide semiconductor, amorphous silicon, or polysilicon. The thin-film transistor 720 further includes another gate insulating layer 743 above the semiconductor layer 724 and another gate electrode 762 above the gate insulating layer 743.

In the configuration example of FIG. 16, the gate insulating layer 723 has a three-layer structure consisting of a lower silicon nitride layer 731, a silicon oxide layer 732 above the lower silicon nitride layer 731, and an upper silicon nitride layer 733 above the silicon oxide layer 732.

The silicon oxide layer 732 of an intermediate insulating layer is in contact with the lower silicon nitride layer 731 and the upper silicon nitride layer 733 and has interfaces with them. In the gate insulating layer 723, the lower silicon nitride layer 731 has an interface with the gate electrode 722 and the upper silicon nitride layer 733 has an interface with the semiconductor layer 724.

The gate insulating layer 743 has a three-layer structure consisting of a lower silicon nitride layer 751, a silicon oxide layer 752 above the lower silicon nitride layer 751, and an upper silicon nitride layer 753 above the silicon oxide layer 752.

The silicon oxide layer 752 of an intermediate insulating layer is in contact with the lower silicon nitride layer 751 and the upper silicon nitride layer 753 and has interfaces with them. In the gate insulating layer 743, the lower silicon nitride layer 751 has an interface with the semiconductor layer 724 and the upper silicon nitride layer 753 has an interface with the gate electrode 762.

The thin-film transistor 720 has a dual-gate structure; the semiconductor layer 724 is located between the top-gate electrode 762 and the bottom-gate electrode 722. The thin-film transistor 720 further includes a source/drain electrode 725 and another source/drain electrode 726. The source/drain electrodes 725 and 726 extend through an interlayer insulating layer 727 and the gate insulating layer 743 and are connected to the semiconductor layer 724.

For the gate insulating layers 723 and 743, the foregoing description provided with reference to the thin-film transistors having a bottom-gate structure is applicable. The gate insulating layers 723 and 743 can have the same configuration or different configurations. For the gate electrodes 722 and 762, the source/drain electrodes 725 and 726, and the interlayer insulating layer 727, the foregoing description about the components having the same names provided with reference to FIG. 3 or 4 is applicable.

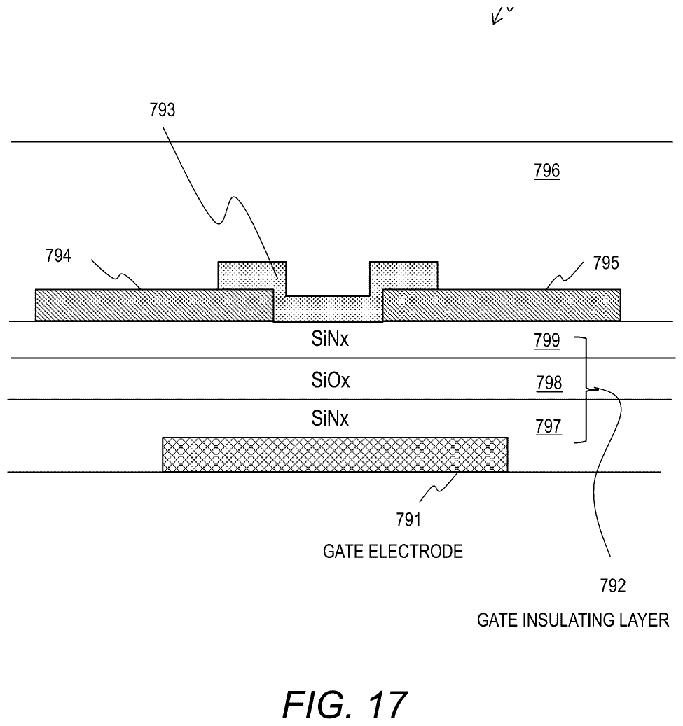

FIG. 17 is a cross-sectional diagram illustrating a structural example of a switching thin-film transistor having a bottom-gate/bottom contact structure. The thin-film transistor 790 includes a gate electrode 791, a gate insulating layer 792 above the gate electrode 791, and source/drain electrodes 794 and 795 above the gate insulating layer 792. The thin-film transistor 790 further includes a semiconductor layer 793 that is in contact with the top faces of the source/drain electrodes 794 and 795. The semiconductor layer 793 can be made of oxide semiconductor, amorphous silicon, or polysilicon. The thin-film transistor 790 further includes an interlayer insulating layer 796 above the source/drain electrodes 794 and 795 and the semiconductor layer 793.

The gate insulating layer 792 in the configuration example of FIG. 17 has a three-layer structure consisting of a lower silicon nitride layer 797, a silicon oxide layer 798 above the lower silicon nitride layer 797, and an upper silicon nitride layer 799 above the silicon oxide layer 798.

The silicon oxide layer 798 of an intermediate insulating layer is in contact with the lower silicon nitride layer 797 and the upper silicon nitride layer 799 and has interfaces with them. In the gate insulating layer 792, the lower silicon nitride layer 797 has an interface with the gate electrode 791 and the upper silicon nitride layer 799 has an interface with the semiconductor layer 793.

For the gate insulating layer 792, the foregoing description provided with reference to the thin-film transistor in FIG. 13 is applicable. For the gate electrode 791, the source/drain electrodes 794 and 795, and the interlayer insulating layer 796, the foregoing description about the components having the same names provided with reference to FIG. 3 or 4 is applicable.

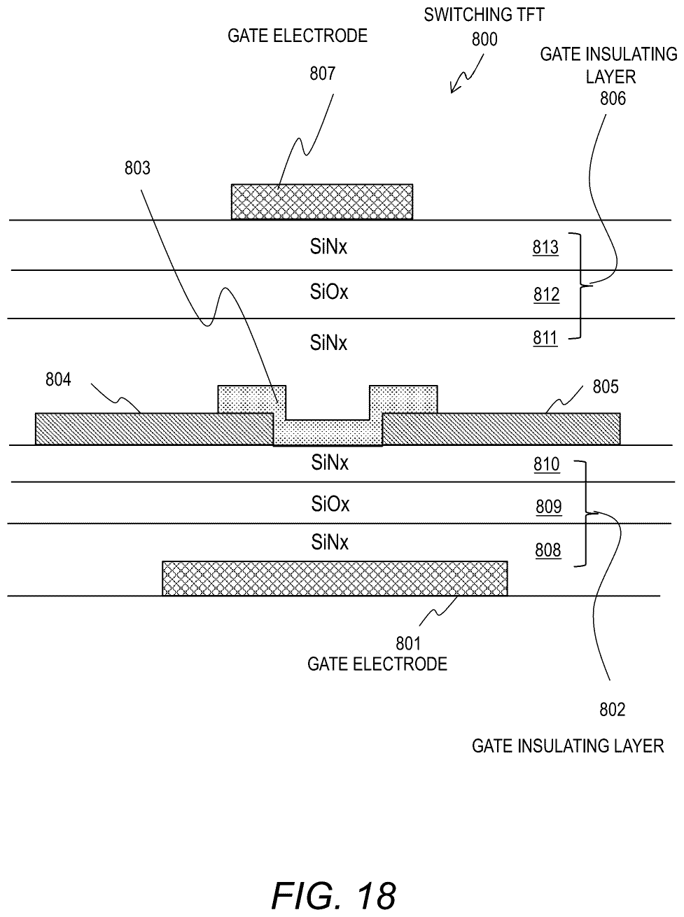

FIG. 18 is a cross-sectional diagram illustrating a structural example of a switching thin-film transistor having a dual-gate structure. The thin-film transistor 800 includes a gate electrode 801, a gate insulating layer 802 above the gate electrode 801, and source/drain electrodes 804 and 805 above the gate insulating layer 802. The thin-film transistor 800 further includes a semiconductor layer 803 that is in contact with the top faces of the source/drain electrodes 804 and 805. The semiconductor layer 803 can be made of oxide semiconductor, amorphous silicon, or polysilicon. The thin-film transistor 800 further includes another gate insulating layer 806 above the source/drain electrodes 804 and 805 and the semiconductor layer 803, and another gate electrode 807 above the gate insulating layer 806.

In the configuration example of FIG. 18, the gate insulating layer 802 has a three-layer structure consisting of a lower silicon nitride layer 808, a silicon oxide layer 809 above the lower silicon nitride layer 808, and an upper silicon nitride layer 810 above the silicon oxide layer 809.

The silicon oxide layer 809 of an intermediate insulating layer is in contact with the lower silicon nitride layer 808 and the upper silicon nitride layer 810 and has interfaces with them. In the gate insulating layer 802, the lower silicon nitride layer 808 has an interface with the gate electrode 801 and the upper silicon nitride layer 810 has an interface with the semiconductor layer 803.

The gate insulating layer 806 has a three-layer structure consisting of a lower silicon nitride layer 811, a silicon oxide layer 812 above the lower silicon nitride layer 811, and an upper silicon nitride layer 813 above the silicon oxide layer 812.

The silicon oxide layer 812 of an intermediate insulating layer is in contact with the lower silicon nitride layer 811 and the upper silicon nitride layer 813 and has interfaces with them. In the gate insulating layer 806, the lower silicon nitride layer 811 has an interface with the semiconductor layer 803 and the upper silicon nitride layer 813 has an interface with the gate electrode 807.

For the gate insulating layers 802 and 806, the foregoing description provided with reference to the thin-film transistor in FIG. 13 is applicable. The gate insulating layers 802 and 806 can have the same configuration or different configurations. For the gate electrodes 801 and 807 and the source/drain electrodes 804 and 805, the foregoing description about the components having the same names provided with reference to FIG. 3 or 4 is applicable.

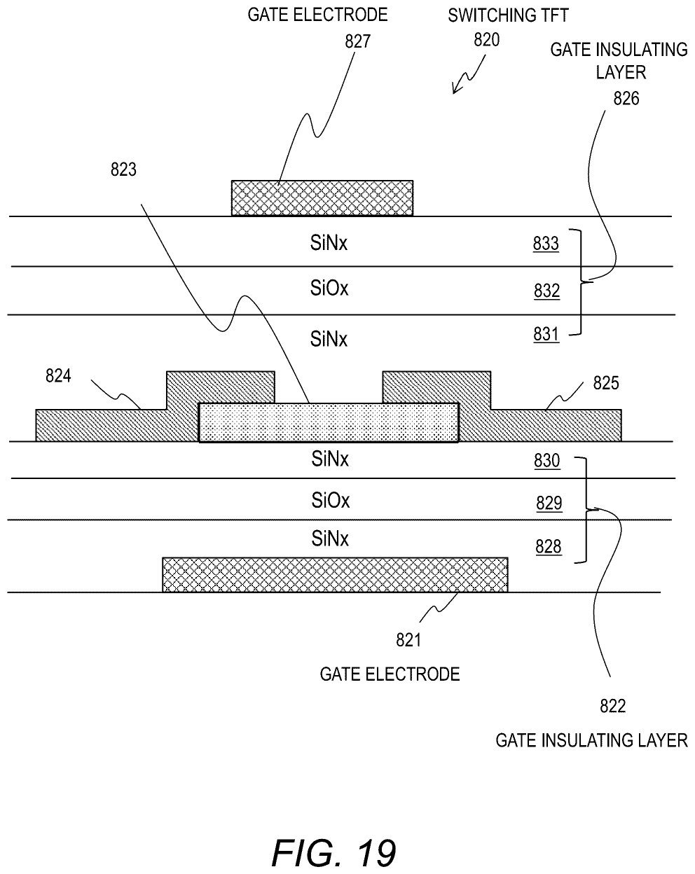

FIG. 19 is a cross-sectional diagram illustrating a structural example of a switching thin-film transistor having a dual-gate structure. The thin-film transistor 820 includes a gate electrode 821, a gate insulating layer 822 above the gate electrode 821, and a semiconductor layer 823 above the gate insulating layer 822. The semiconductor layer 823 can be made of oxide semiconductor, amorphous silicon, or polysilicon. The thin-film transistor 820 further includes source/drain electrodes 824 and 825 above the semiconductor layer 823, another gate insulating layer 826 above the source/drain electrodes 824 and 825 and the semiconductor layer 823, and another gate electrode 827 above the gate insulating layer 826.

In the configuration example of FIG. 19, the gate insulating layer 822 has a three-layer structure consisting of a lower silicon nitride layer 828, a silicon oxide layer 829 above the lower silicon nitride layer 828, and an upper silicon nitride layer 830 above the silicon oxide layer 829.

The silicon oxide layer 829 of an intermediate insulating layer is in contact with the lower silicon nitride layer 828 and the upper silicon nitride layer 830 and has interfaces with them. In the gate insulating layer 822, the lower silicon nitride layer 828 has an interface with the gate electrode 821 and the upper silicon nitride layer 830 has an interface with the semiconductor layer 823.

The gate insulating layer 826 has a three-layer structure consisting of a lower silicon nitride layer 831, a silicon oxide layer 832 above the lower silicon nitride layer 831, and an upper silicon nitride layer 833 above the silicon oxide layer 832.

The silicon oxide layer 832 of an intermediate insulating layer is in contact with the lower silicon nitride layer 831 and the upper silicon nitride layer 833 and has interfaces with them. In the gate insulating layer 826, the lower silicon nitride layer 831 has an interface with the semiconductor layer 823 and the upper silicon nitride layer 833 has an interface with the gate electrode 827.

For the gate insulating layers 822 and 826, the foregoing description provided with reference to the thin-film transistor in FIG. 13 is applicable. The gate insulating layers 822 and 826 can have the same configuration or different configurations. For the gate electrodes 821 and 827 and the source/drain electrodes 824 and 825, the foregoing description about the components having the same names provided with reference to FIG. 3 or 4 is applicable.

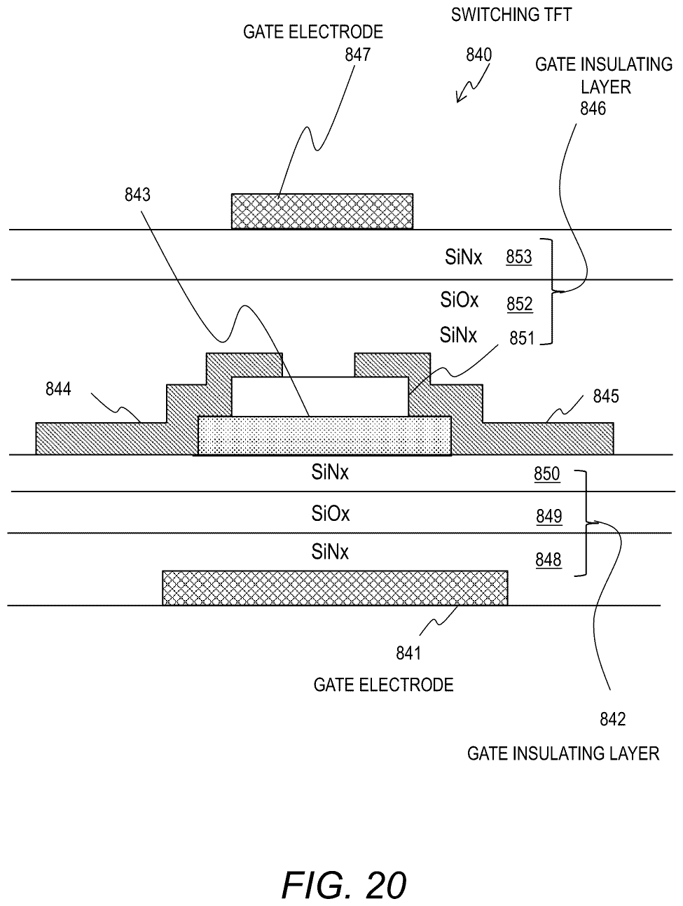

FIG. 20 is a cross-sectional diagram illustrating a structural example of a switching thin-film transistor having a dual-gate structure. The thin-film transistor 840 includes a gate electrode 841, a gate insulating layer 842 above the gate electrode 841, and a semiconductor layer 843 above the gate insulating layer 842. The semiconductor layer 843 can be made of oxide semiconductor, amorphous silicon, or polysilicon. The thin-film transistor 840 further includes another gate insulating layer 846 above the semiconductor layer 843 and another gate electrode 847 above the gate insulating layer 846.

In the configuration example of FIG. 20, the gate insulating layer 842 has a three-layer structure consisting of a lower silicon nitride layer 848, a silicon oxide layer 849 above the lower silicon nitride layer 848, and an upper silicon nitride layer 850 above the silicon oxide layer 849.

The silicon oxide layer 849 of an intermediate insulating layer is in contact with the lower silicon nitride layer 848 and the upper silicon nitride layer 850 and has interfaces with them. In the gate insulating layer 842, the lower silicon nitride layer 848 has an interface with the gate electrode 841 and the upper silicon nitride layer 850 has an interface with the semiconductor layer 843.

The gate insulating layer 846 has a three-layer structure consisting of a lower silicon nitride layer 851, a silicon oxide layer 852 above the lower silicon nitride layer 851, and an upper silicon nitride layer 853 above the silicon oxide layer 852.

The silicon oxide layer 852 of an intermediate insulating layer is in contact with the lower silicon nitride layer 851 and the upper silicon nitride layer 853 and has interfaces with them. In the gate insulating layer 846, the lower silicon nitride layer 851 has an interface with the semiconductor layer 843 and the upper silicon nitride layer 853 has an interface with the gate electrode 847.

The thin-film transistor 840 has a dual-gate structure; the semiconductor layer 843 is located between the top-gate electrode 847 and the bottom-gate electrode 841. The thin-film transistor 840 further includes a source/drain electrode 844 and another source/drain electrode 845. The source/drain electrodes 844 and 845 are provided above the lower silicon nitride layer 851 of the gate insulating layer 846, the semiconductor layer 843, and the upper silicon nitride layer 850 of the gate insulating layer 842.

For the gate insulating layers 842 and 846, the foregoing description provided with reference to the thin-film transistor in FIG. 13 is applicable. The gate insulating layers 842 and 846 can have the same configuration or different configurations. For the gate electrodes 841 and 847 and the source/drain electrodes 844 and 845, the foregoing description about the components having the same names provided with reference to FIG. 3 or 4 is applicable.

FIG. 21 is a cross-sectional diagram illustrating a structural example of a switching thin-film transistor having a dual-gate structure. The thin-film transistor 860 includes a gate electrode 861, a gate insulating layer 862 above the gate electrode 861, and a semiconductor layer 863 above the gate insulating layer 862. The semiconductor layer 863 can be made of oxide semiconductor, amorphous silicon, or polysilicon. The thin-film transistor 860 further includes another gate insulating layer 866 above the semiconductor layer 863 and another gate electrode 867 above the gate insulating layer 866.

In the configuration example of FIG. 21, the gate insulating layer 862 has a three-layer structure consisting of a lower silicon nitride layer 868, a silicon oxide layer 869 above the lower silicon nitride layer 868, and an upper silicon nitride layer 870 above the silicon oxide layer 869.

The silicon oxide layer 869 of an intermediate insulating layer is in contact with the lower silicon nitride layer 868 and the upper silicon nitride layer 870 and has interfaces with them. In the gate insulating layer 862, the lower silicon nitride layer 868 has an interface with the gate electrode 861 and the upper silicon nitride layer 870 has an interface with the semiconductor layer 863.

The gate insulating layer 866 has a three-layer structure consisting of a lower silicon nitride layer 871, a silicon oxide layer 872 above the lower silicon nitride layer 871, and an upper silicon nitride layer 873 above the silicon oxide layer 872.

The silicon oxide layer 872 of an intermediate insulating layer is in contact with the lower silicon nitride layer 871 and the upper silicon nitride layer 873 and has interfaces with them. In the gate insulating layer 866, the lower silicon nitride layer 871 has an interface with the semiconductor layer 863 and the upper silicon nitride layer 873 has an interface with the gate electrode 867.

The thin-film transistor 860 has a dual-gate structure; the semiconductor layer 863 is located between the top-gate electrode 867 and the bottom-gate electrode 861. The thin-film transistor 860 further includes a source/drain electrode 864 and another source/drain electrode 865. The source/drain electrodes 864 and 865 are provided above the silicon oxide layer 872 of the intermediate insulating layer of the gate insulating layer 866, the semiconductor layer 863, and the upper silicon nitride layer 870 of the gate insulating layer 862.

For the gate insulating layers 862 and 866, the foregoing description provided with reference to the thin-film transistor in FIG. 13 is applicable. The gate insulating layers 862 and 866 can have the same configuration or different configurations. For the gate electrodes 861 and 867 and the source/drain electrodes 864 and 865, the foregoing description about the components having the same names provided with reference to FIG. 3 or 4 is applicable.

### Second Embodiment

Hereinafter, results of an experiment conducted by the inventors and embodiments based thereon are described with reference to the accompanying drawings. The embodiments are merely an example to implement this disclosure and are not to limit the technical scope of this disclosure. Some elements in the drawings may be exaggerated in size or shape for clear understanding of the description.

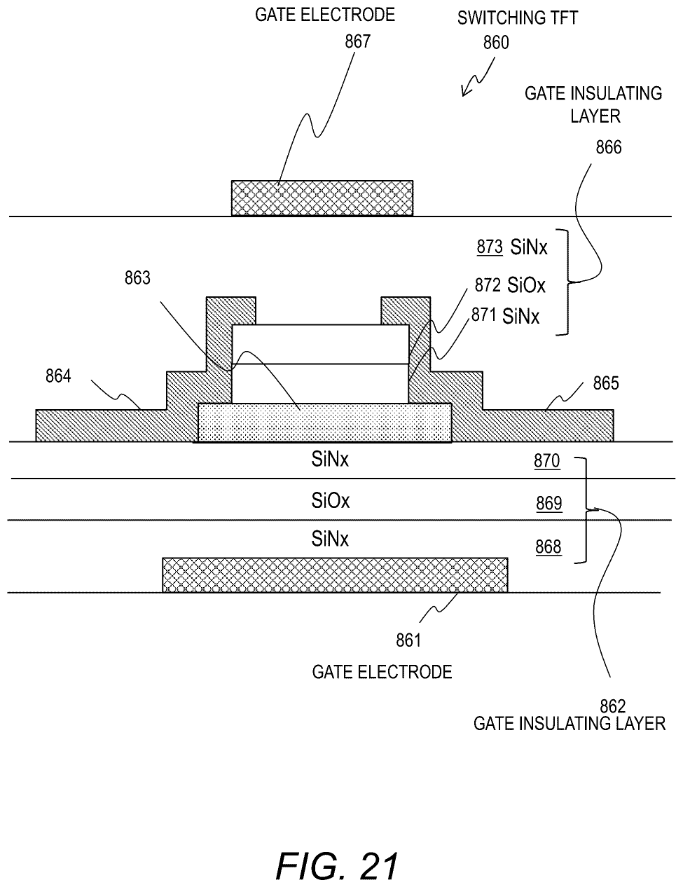

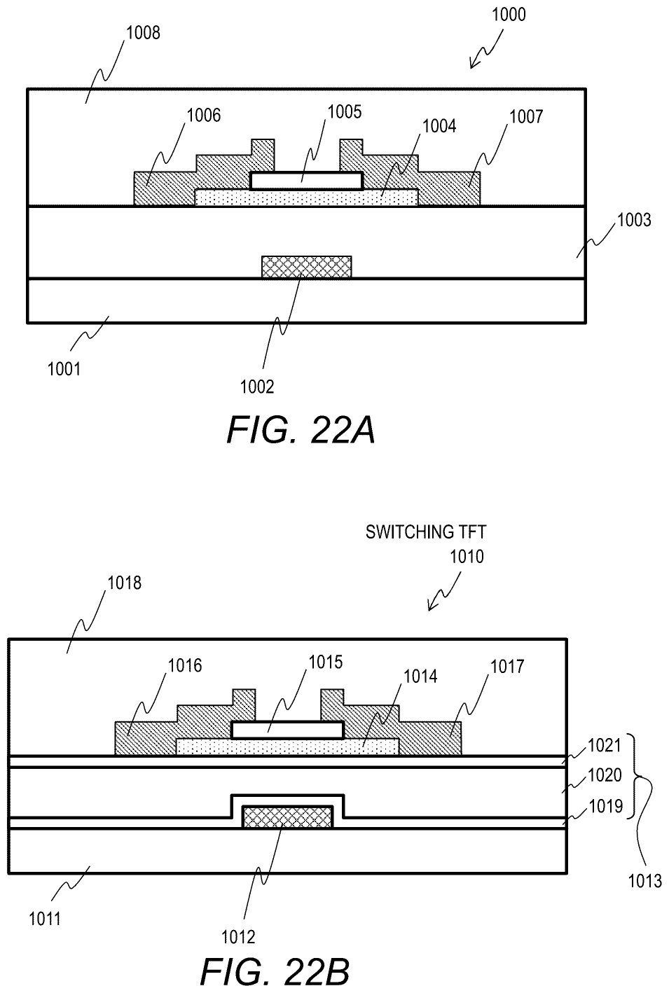

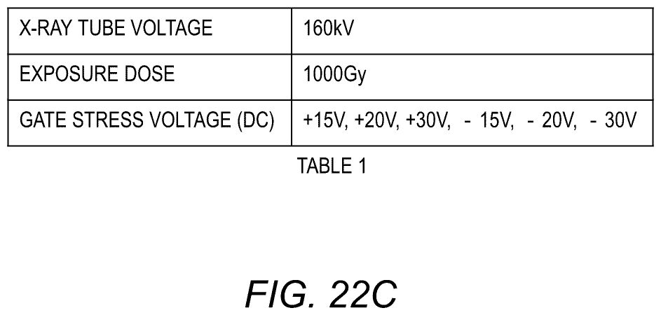

FIG. 22A is a cross-sectional diagram schematically illustrating the structure of a thin-film transistor used in the experiment. The switching thin-film transistor 1000 includes a gate electrode 1002 on a glass substrate 1001, a gate insulating layer 1003 above the gate electrode 1002, and an oxide semiconductor layer 1004 above the gate insulating layer 1003. The gate insulating layer 1003 is a silicon nitride film having a thickness of 420 nm and the oxide semiconductor layer 1004 is made of IGZO. The switching thin-film transistor 1000 further includes an etch stop layer 1005 above the oxide semiconductor layer 1004 and source/drain electrodes 1006 and 1007 above the gate insulating layer 1003, the oxide semiconductor layer 1004, and the etch stop layer 1005. The entire thin-film transistor 1000 is covered with an interlayer insulating layer 1008.

FIG. 22B is a cross-sectional diagram schematically illustrating the structure of another thin-film transistor used in the experiment. The switching thin-film transistor 1010 includes a gate electrode 1012 on a glass substrate 1011, a gate insulating layer 1013 above the gate electrode 1012, and an oxide semiconductor layer 1014 above the gate insulating layer 1013. The gate insulating layer 1013 has a three-layer structure consisting of a lower silicon nitride layer 1019 having a film thickness of 100 nm, a silicon oxide layer 1020 having a film thickness of 300 nm above the lower silicon nitride layer 1019, and an upper silicon nitride layer 1021 having a film thickness of 20 nm above the silicon oxide layer 1020. The oxide semiconductor layer 1014 is made of IGZO. The switching thin-film transistor 1010 further includes an etch stop layer 1015 above the oxide semiconductor layer 1014 and source/drain electrodes 1016 and 1017 above the gate insulating layer 1013, the oxide semiconductor layer 1014, and the etch stop layer 1015. The entire thin-film transistor 1010 is covered with an interlayer insulating layer 1018.

An X-ray irradiation experiment was conducted on the switching thin-film transistors 1000 and 1010. A mediXtec MX-160Labo X-ray irradiation system was used in the experiment. The X-ray radiation conditions are provided in Table 1 in FIG. 22C. The transistors were supplied with the gate stress voltages in Table 1 under X ray irradiation.

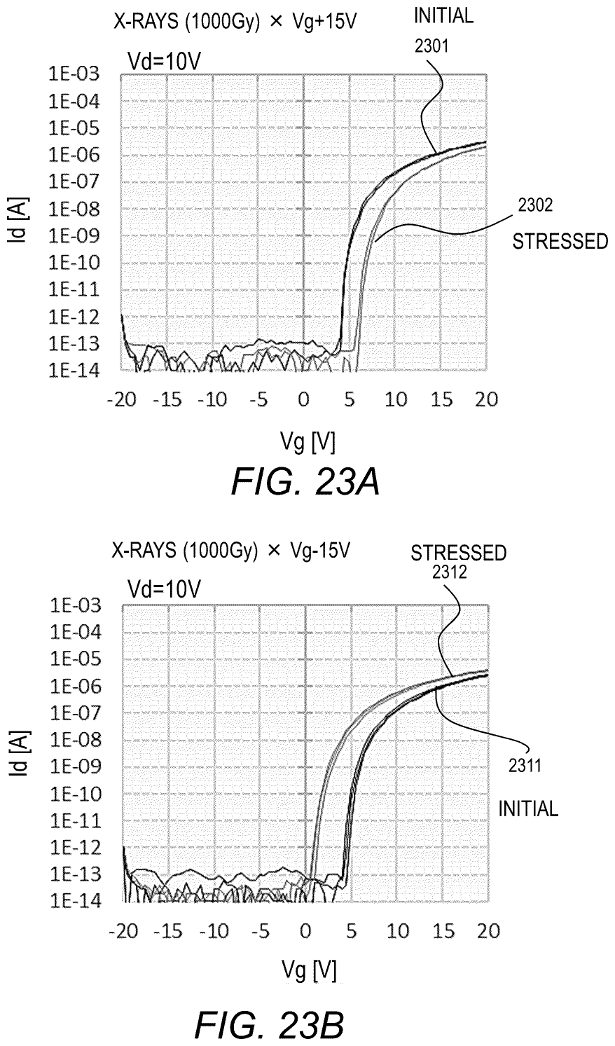

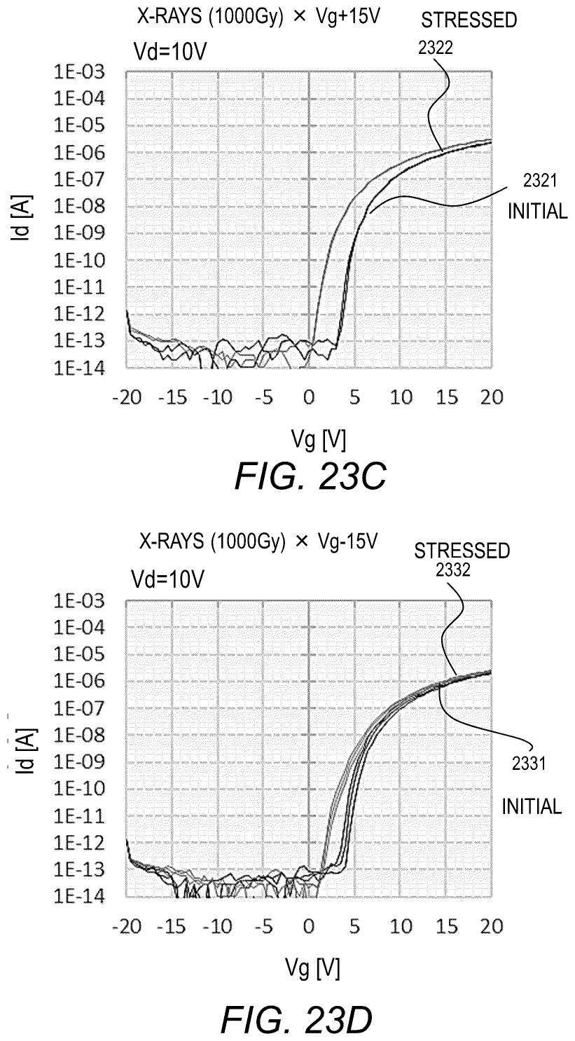

FIG. 23A illustrates the difference in Vg-Id characteristic of a thin-film transistor 1000 having the structure of FIG. 22A between before and after application of a gate voltage of +15 V under 1000 Gy of X-rays. FIG. 23B illustrates the difference in Vg-Id characteristic of the thin-film transistor 1000 between before and after application of a gate voltage of −15 V under 1000 Gy of X-rays. The horizontal axes of these graphs represent the gate voltage Vg and the vertical axes represent the drain current Id. The drain voltage Vd was 10 V.

In the graphs of FIGS. 23A and 23B, the curves 2301 and 2311 represent the Vg-Id characteristic of the thin-film transistor 1000 as described above before the positive or negative Vg stress was applied (initial state) under X ray irradiation. The curves 2302 and 2312 represent the Vg-Id characteristic of the thin-film transistor 1000 as described above after the positive or negative Vg stress was applied (stressed state) under X ray irradiation. As understood from the differences in the characteristic in FIGS. 23A and 23B, the thin-film transistor 1000 properly turns ON/OFF in response to variation in gate voltage, although the Vg-Id characteristic of the thin-film transistor 1000 shifts toward the positive side in the case of the positive Vg stress under X ray irradiation and toward the negative side in the case of the negative Vg stress under X ray irradiation.

FIG. 23C illustrates the difference in Vg-Id characteristic of a thin-film transistor 1010 having the structure of FIG. 22B between before and after application of a gate voltage of +15 V under 1000 Gy of X-rays. FIG. 23D illustrates the difference in Vg-Id characteristic of the thin-film transistor 1010 between before and after application of a gate voltage of −15 V under 1000 Gy of X-rays. The horizontal axes of these graphs represent the gate voltage Vg and the vertical axes represent the drain current Id. The drain voltage Vd was 10 V.

In the graphs of FIGS. 23C and 23D, the curves 2321 and 2331 represent the Vg-Id characteristic of the thin-film transistor 1010 as described above before the positive or negative Vg stress was applied (initial state) under X ray irradiation. The curves 2322 and 2332 represent the Vg-Id characteristic of the thin-film transistor 1010 as described above after the positive or negative Vg stress was applied (stressed state) under X ray irradiation. As understood from the differences in the characteristic in FIGS. 23C and 23D, the thin-film transistor 1010 properly turns ON/OFF in response to variation in gate voltage, although the Vg-Id characteristic of the thin-film transistor 1010 shifts toward the negative side in either case of application of the positive or negative Vg stress under X ray irradiation.

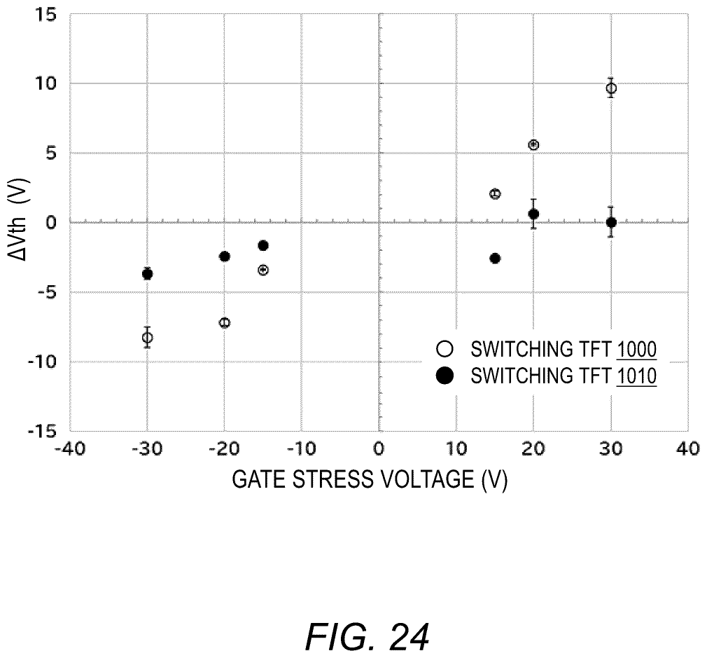

The thin-film transistors 1000 and 1010 were further tested by applying different positive and negative Vg stresses under irradiation with X-rays. FIG. 24 provides the results. The horizontal axis represents the gate stress voltage and the vertical axis represents the amount of shift ΔVth of the Vg-Id characteristic after application of the Vg stress. According to the results in FIG. 24, the thin-film transistor 1000 exhibited ΔVth within the range from −5 V to +5 V when the applied Vg stresses were +15 V and −15 V but the value of ΔVth exceeded the range from −5 V to +5 V when the applied Vg stresses were not less than +20 V and not more than −20 V, whereas the thin-film transistor 1010 exhibited ΔVth within the range from −5 V to +5 V even when the applied Vg stresses were +30 V and −30 V. This means that the thin-film transistor 1010 has higher reliability than the thin-film transistor 1000 under irradiation with X-rays.

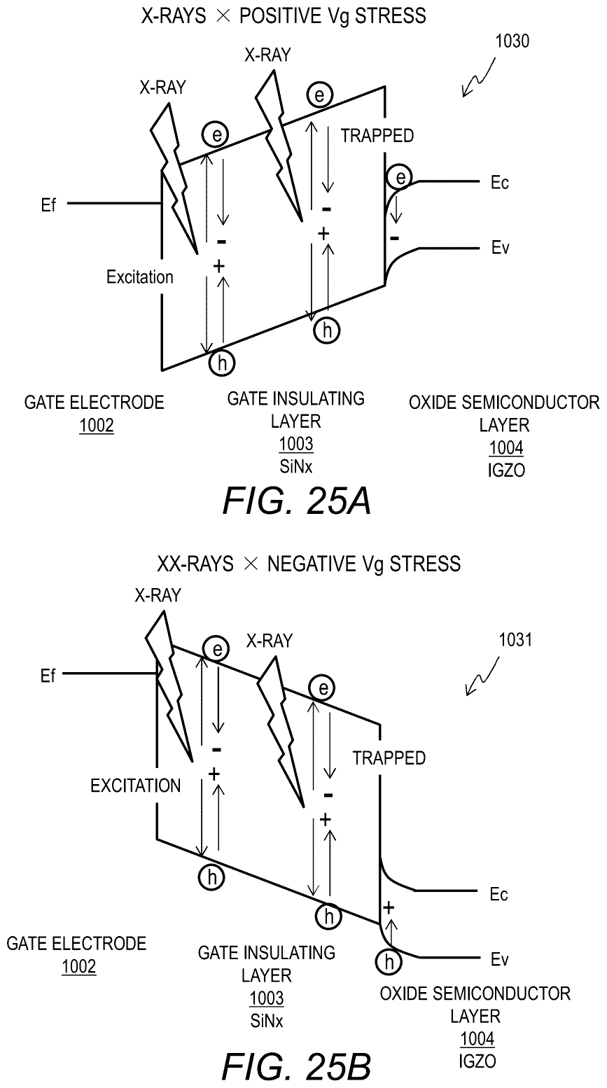

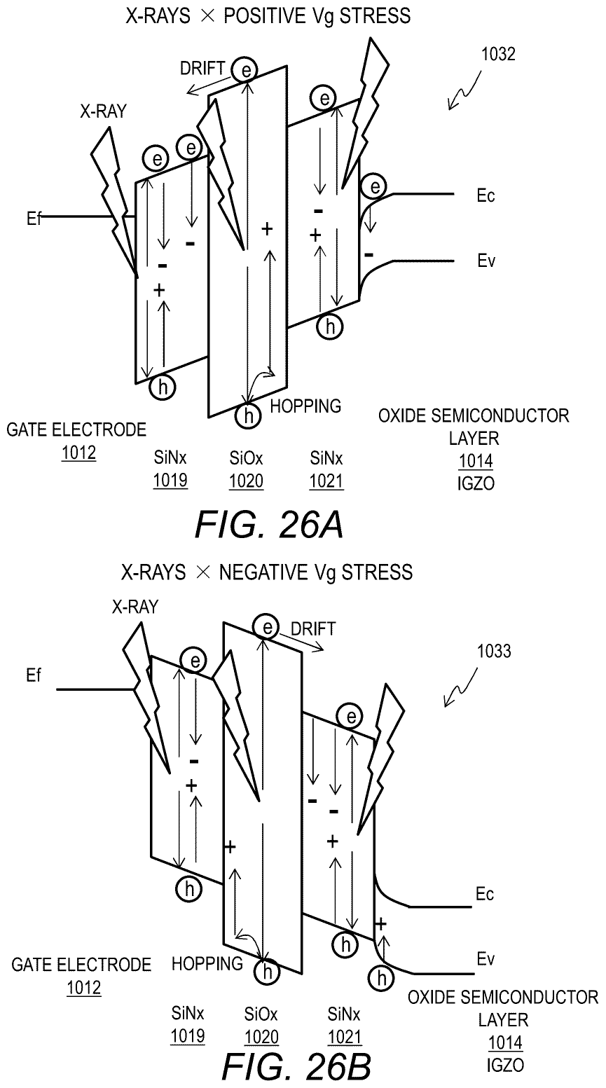

The results in FIG. 24 are described with reference to FIGS. 25A, 25B, 26A, and 26B, which are extended from the band diagrams in FIG. 14. FIGS. 25A and 25B are band diagrams for illustrating the movement of carriers when the thin-film transistor 1000 is being irradiated with X-rays. The band diagram 1030 in FIG. 25A illustrates the electron energy levels of the gate electrode 1002, the gate insulating layer 1003, and the oxide semiconductor layer 1004 when a positive gate voltage is applied to the thin-film transistor 1000 under X ray irradiation. In the diagram 1030, Ec represents the lower edges of the conduction bands of the oxide semiconductor layer 1004 and the gate insulating layer 1003; Ev represents the upper edges of the valence bands of the oxide semiconductor layer 1004 and the gate insulating layer 1003; and Ef represents the fermi level of the gate electrode 1002 (the metal layer). The diagram 1030 is configured so that the band gaps of silicon nitride and oxide semiconductor are approximately 5.1 eV and 3.1 eV, respectively.

The electrons (e) generated in the gate insulating layer 1003 because of X-rays are trapped in the electron trap states in the gate insulating layer 1003. The holes (h) generated in the gate insulating layer 1003 are trapped in the hole trap states in the gate insulating layer 1003. Accordingly, the balance between electrons and holes in the gate insulating layer 1003 does not change very much.

On the other hand, the electrons (e) generated in the oxide semiconductor layer 1004 because of X-rays drift to the vicinity of the interface between the gate insulating layer 1003 and the oxide semiconductor layer 1004 in response to the positive gate voltage and are trapped there. Accordingly, the potential of the oxide semiconductor layer 1004 varies, so that the Vg-Id characteristic of the thin-film transistor 1000 shifts toward the positive side.

The band diagram 1031 in FIG. 25B illustrates the electron energy levels of the gate electrode 1002, the gate insulating layer 1003, and the oxide semiconductor layer 1004 when a negative gate voltage is applied to the thin-film transistor 1000 under X ray irradiation. The reference signs Ec, Ev, and Ef and the band gaps of silicon nitride and oxide semiconductor are the same as those in the band diagram 1030.

The electrons (e) and holes (h) generated in the gate insulating layer 1003 because of X-rays are trapped in the electron trap states and hole trap states, respectively, in the gate insulating layer 1003 like those in the band diagram 1030. Accordingly, the balance between electrons and holes in the gate insulating layer 1003 does not change very much.

On the other hand, the holes generated in the oxide semiconductor layer 1004 because of X-rays drift to the vicinity of the interface between the gate insulating layer 1003 and the oxide semiconductor layer 1004 in response to the negative gate voltage and are trapped there. Accordingly, the potential of the oxide semiconductor layer 1004 varies, so that the Vg-Id characteristic of the thin-film transistor 1000 shifts toward the negative side.

FIGS. 26A and 26B are band diagrams for illustrating the movement of carriers when the thin-film transistor 1010 is being irradiated with X-rays. The band diagram 1032 in FIG. 26A illustrates the electron energy levels of the gate electrode 1012, the lower silicon nitride layer 1019, the silicon oxide layer 1020, the upper silicon nitride layer 1021, and the oxide semiconductor layer 1014 when a positive gate voltage is applied to the thin-film transistor 1010 under X ray irradiation. In the diagram 1032, Ec represents the lower edges of the conduction bands of the oxide semiconductor layer 1014, the lower silicon nitride layer 1019, the silicon oxide layer 1020, and the upper silicon nitride layer 1021; Ev represents the upper edges of the valence bands of the oxide semiconductor layer 1014, the lower silicon nitride layer 1019, the silicon oxide layer 1020, and the upper silicon nitride layer 1021; and Ef represents the fermi level of the gate electrode 1012 (the metal layer). The diagram 1032 is configured so that the band gaps of silicon oxide, silicon nitride, and oxide semiconductor are approximately 8.8 eV, 5.1 eV and 3.1 eV, respectively.

The electrons (e) generated in the lower silicon nitride layer 1019 because of X-rays are trapped in the electron trap states in the lower silicon nitride layer 1019. The holes (h) generated in the lower silicon nitride layer 1019 are trapped in the hole trap states in the lower silicon nitride layer 1019.

In similar, the electrons (e) generated in the upper silicon nitride layer 1021 because of X-rays are trapped in the electron trap states in the upper silicon nitride layer 1021. The holes (h) generated in the upper silicon nitride layer 1021 are trapped in the hole trap states in the upper silicon nitride layer 1021.

The electrons (e) generated in the silicon oxide layer 1020 because of X-rays drift to the lower silicon nitride layer 1019 having lower energy levels and are trapped in the electron trap states in the lower silicon nitride layer 1019. The holes (h) generated in the silicon oxide layer 1020 are trapped in the hole trap states in the silicon oxide layer 1020. As a result, positive charges are stored in the vicinity of the interface between the silicon oxide layer 1020 and the upper silicon nitride layer 1021.

The electrons (e) generated in the oxide semiconductor layer 1014 because of X-rays drift to the vicinity of the interface between the upper silicon nitride layer 1021 and the oxide semiconductor layer 1014 in response to the positive gate voltage and are trapped there. The negative charges caused by the trapped electrons and the positive charges stored in the vicinity of the interface between the silicon oxide layer 1020 and the upper silicon nitride layer 1021 cancel each other, so that the variation in potential of the oxide semiconductor layer 1014 is small, suppressing the shift of the Vg-Id characteristic of the thin-film transistor 1010.

The band diagram 1033 in FIG. 26B illustrates the electron energy levels of the gate electrode 1012, the lower silicon nitride layer 1019, the silicon oxide layer 1020, the upper silicon nitride layer 1021, and the oxide semiconductor layer 1014 when a negative gate voltage is applied to the thin-film transistor 1010 under X ray irradiation. The reference signs Ec, Ev, and Ef and the band gaps of silicon oxide, silicon nitride, and oxide semiconductor are the same as those in the band diagram 1032.

The electrons (e) and holes (h) generated in the lower silicon nitride layer 1019 because of X-rays are trapped in the electron trap states and hole trap states, respectively, in the lower silicon nitride layer 1019.

In similar, the electrons (e) generated in the upper silicon nitride layer 1021 because of X-rays are trapped in the electron trap states in the upper silicon nitride layer 1021. The holes (h) generated in the upper silicon nitride layer 1021 because of X-rays are trapped in the hole trap states in the upper silicon nitride layer 1021.

The electrons (e) generated in the silicon oxide layer 1020 because of X-rays drift to the upper silicon nitride layer 1021 having lower energy levels and are trapped in the electron trap states in the upper silicon nitride layer 1021. As a result, negative charges are stored in the vicinity of the interface between the silicon oxide layer 1020 and the upper silicon nitride layer 1021. The holes (h) generated in the silicon oxide layer 1020 are trapped in the hole trap states in the silicon oxide layer 1020.

The holes (e) generated in the oxide semiconductor layer 1014 because of X-rays drift to the vicinity of the interface between the upper silicon nitride layer 1021 and the oxide semiconductor layer 1014 in response to the negative gate voltage and are trapped there. The positive charges caused by the trapped holes and the negative charges stored in the vicinity of the interface between the silicon oxide layer 1020 and the upper silicon nitride layer 1021 cancel each other, so that the variation in potential of the oxide semiconductor layer 1014 is small, suppressing the shift of the Vg-Id characteristic of the thin-film transistor 1010.

The inventors consider that, because of the above-described mechanisms, the thin-film transistor including a gate insulating film having a three-layer structure consisting of a lower silicon nitride layer, a silicon oxide layer above the lower silicon nitride layer, and an upper silicon nitride layer above the silicon oxide layer exhibited higher reliability than the thin-film transistor including a silicon nitride gate insulating film under irradiation with X-rays.

As set forth above, embodiments of this disclosure have been described, however, this disclosure is not limited to the foregoing embodiments. Those skilled in the art can easily modify, add, or convert each element in the foregoing embodiments within the scope of this disclosure. A part of the configuration of one embodiment can be replaced with a configuration of another embodiment or a configuration of an embodiment can be incorporated into a configuration of another embodiment.

What is claimed is:

1. A thin-film transistor to be used in an X-ray sensor, the thin-film transistor comprising:
a gate electrode;
a semiconductor layer; and
a gate insulating layer located between the semiconductor layer and the gate electrode,
wherein the gate insulating layer includes a first region having an interface with the gate electrode, a second region having an interface with the semiconductor layer, and a third region located between the first region and the second region, and
wherein each of the first region and the second region has a density of electron trap states and a density of hole trap states that are higher than whichever of a density of electron trap states and a density of hole trap states of the third region that is lower.

2. The thin-film transistor according to claim 1, wherein each of the first region and the second region has a higher hydrogen concentration than the third region.

3. The thin-film transistor according to claim 1, wherein the density of the electron trap states of the first region and the second region are not less than 7e11 cm⁻² eV⁻¹.

4. The thin-film transistor according to claim 1, wherein the first region and the second regions are nitride regions and the third region is an oxide region.

5. The thin-film transistor according to claim 1, wherein the gate insulating layer has a three-layer structure.

6. The thin-film transistor according to claim 1, wherein each of the first region and the second region has a density of electron trap states substantially equal to a density of hole trap states.

7. A thin-film transistor to be used in an X-ray sensor, the thin-film transistor comprising:
a gate electrode;
a semiconductor layer; and
a gate insulating layer located between the semiconductor layer and the gate electrode,
wherein the gate insulating layer includes a first region having an interface with the gate electrode and a second region having an interface with the semiconductor layer, and
wherein each of the first region and the second region has a density of electron trap states substantially equal to a density of hole trap states.

8. The thin-film transistor according to claim 7,
wherein the gate insulating layer further includes a third region located between the first region and the second region, and
wherein each of the first region and the second region has a higher hydrogen concentration than the third region.

9. The thin-film transistor according to claim 7, wherein the density of the electron trap states of the first region and the second region are not less than 7e11 cm⁻² eV⁻¹.

10. The thin-film transistor according to claim 7, wherein the first region and the second region are nitride regions.

11. A thin-film transistor to be used in an X-ray sensor, the thin-film transistor comprising:
a gate electrode;
a semiconductor layer; and
a gate insulating layer located between the semiconductor layer and the gate electrode,
wherein the gate insulating layer includes a first region having an interface with the gate electrode, a second region having an interface with the semiconductor layer, and a third region made of a material different from materials of the first region and the second region and located between the first region and the second region, and
wherein each of the first region and the second region is made of a nitride.

12. The thin-film transistor according to claim 11, wherein the third region is made of an oxide.

13. The thin-film transistor according to claim 12, wherein each of the first region and the second region has a higher hydrogen concentration than the third region.

14. The thin-film transistor according to claim 12, wherein the density of the electron trap states of the first region and the second region are not less than 7e11 cm⁻² eV⁻¹.

15. The thin-film transistor according to claim 12, wherein the gate insulating layer has a three-layer structure.

16. The thin-film transistor according to claim 12, wherein each of the first region and the second region has a density of electron trap states substantially equal to a density of hole trap states.

17. The thin-film transistor according to claim 1,
wherein the gate electrode and the gate insulating layer are located upper than the semiconductor layer, and
wherein the thin-film transistor further comprises a second gate electrode located lower than the semiconductor layer and a second gate insulating layer located between the semiconductor layer and the second gate electrode.

18. An X-ray sensor comprising:
a plurality of pixels; and
a signal line,
wherein each of the plurality of pixels includes a conversion element that converts electromagnetic rays into an electric signal and the thin-film transistor according to claim 1, and
wherein the thin-film transistor is located between the conversion element and the signal line and controlled to be ON/OFF.

19. An X-ray sensor comprising:
a plurality of pixels; and
a signal line,
wherein each of the plurality of pixels includes a conversion element that converts electromagnetic rays into an electric signal and the thin-film transistor according to claim 7, and
wherein the thin-film transistor is located between the conversion element and the signal line and controlled to be ON/OFF.

20. An X-ray sensor comprising:
a plurality of pixels; and
a signal line,
wherein each of the plurality of pixels includes a conversion element that converts electromagnetic rays into an electric signal and the thin-film transistor according to claim 11, and
wherein the thin-film transistor is located between the conversion element and the signal line and controlled to be ON/OFF.
